(19) United States
(12) Patent Application Publication
(10) Pub. No.: US 2024/0079383 A1
(43) Pub. Date: Mar. 7, 2024

(54) SEMICONDUCTOR DEVICE

(71) Applicant: DENSO CORPORATION, Kariya-city (JP)

(72) Inventors: TAKANORI KAWASHIMA, Kariya-city (JP); TOMOMI OKUMURA, Kariya-city (JP)

(21) Appl. No.: 18/507,421

(22) Filed: Nov. 13, 2023

Related U.S. Application Data
(63) Continuation of application No. PCT/JP2022/020499, filed on May 17, 2022.

(30) Foreign Application Priority Data
Jun. 16, 2021 (JP) 2021-100437

(51) Int. Cl. H01L 25/07; H01L 23/00; H01L 23/34; H01L 23/495; H01L 23/498

(52) U.S. Cl. CPC H01L 25/072; H01L 23/34; H01L 23/49562; H01L 23/49844; H01L 24/32; H01L 24/48; H01L 24/73; H01L 2224/32225; H01L 2224/48225; H01L 2224/73265

(57) ABSTRACT

In a semiconductor device, a plurality of semiconductor elements includes a first element and a second element arranged in a first direction perpendicular to a plate thickness direction. The first element and the second element each have a rectangular shape having four corner portions and four side portions. The first element and the second element have structures common to each other, in which pads are offset to a periphery of a first corner portion between a first side portion and a second side portion. The first element is disposed so that the first side portion faces signal terminals in a second direction, and the second side portion faces the second element in the first direction. The second element is disposed so that the second side portion faces the signal terminals in the second direction and the first side portion faces the first element in the first direction.

### CROSS REFERENCE TO RELATED APPLICATIONS

The present application is a continuation application of International Patent Application No. PCT/JP2022/020499 filed on May 17, 2022, which designated the U.S. and claims the benefit of priority from Japanese Patent Application No. 2021-100437 filed on Jun. 16, 2021. The entire disclosures of all of the above applications are incorporated herein by reference.

### TECHNICAL FIELD

The present disclosure relates to a semiconductor device.

### BACKGROUND

JP 2019-176058 A discloses a semiconductor device including a plurality of semiconductor elements (switching elements) each having main electrodes on both surfaces thereof and a plurality of signal terminals (control terminals) electrically connected to the semiconductor elements via bonding wires. The contents in JP 2019-176058 A is incorporated herein by reference as explanation of the technical elements in this description.

### SUMMARY

The present disclosure provides a semiconductor device including a plurality of semiconductor elements each having a first main electrode and a second main electrode on opposite surfaces, a wiring member connected to the first main electrode of each semiconductor element, a plurality of signal terminals connected to a circuit substrate, and a plurality of bonding wires electrically connecting pads on the semiconductor elements and the signal terminals.

### BRIEF DESCRIPTION OF DRAWINGS

Features and advantages of the present disclosure will become more apparent from the following detailed description made with reference to the accompanying drawings, in which:

FIG. 1 is a diagram illustrating a circuit configuration of an electric power conversion device to which a semiconductor device according to a first embodiment is applied;

FIG. 2 is a perspective view illustrating the semiconductor device according to the first embodiment;

FIG. 3 is a plan view viewed in a direction along an arrow Z1 in FIG. 2;

FIG. 4 is a cross-section view taken along a line IV-IV in FIG. 3;

FIG. 5 is a cross-section view taken along a line V-V in FIG. 3;

FIG. 6 is a cross-section view taken along a line VI-VI in FIG. 3;

FIG. 7 is a cross-section view taken along a line VII-VII in FIG. 3;

FIG. 8 is a plan view illustrating a state where semiconductor elements are mounted on a substrate;

FIG. 9 is a plan view illustrating a circuit pattern of the substrate on a drain electrode side;

FIG. 10 is a plan view illustrating a circuit pattern of the substrate on a source electrode side;

FIG. 11 is a plan view illustrating placement of the semiconductor elements connected in parallel;

FIG. 12 is a plan view illustrating a structure around the semiconductor elements and signal terminals on a lower arm side;

FIG. 13 is a plan view illustrating a structure around the semiconductor elements and signal terminals on an upper arm side;

FIG. 14 is a perspective view illustrating a bent state of the signal terminals;

FIG. 15 is a side view illustrating a connection structure between the signal terminals and a circuit substrate, which is viewed in a direction along an arrow X1 in FIG. 11;

FIG. 16 is a plan view illustrating a reference example;

FIG. 17 is a diagram illustrating dead spaces of the circuit substrate;

FIG. 18 is a plan view illustrating the reference example;

FIG. 19 is a plan view illustrating the reference example;

FIG. 20 is a plan view illustrating a structure around semiconductor elements and signal terminals on a lower arm side in a semiconductor device according to a second embodiment;

FIG. 21 is a plan view illustrating a structure of the semiconductor elements and the signal terminals on an upper arm side;

FIG. 22 is a plan view illustrating a structure around semiconductor elements and signal terminals on a lower arm side in a semiconductor device according to a third embodiment;

FIG. 23 is a plan view illustrating a structure of the semiconductor elements and the signal terminals on an upper arm side;

FIG. 24 is a plan view illustrating a modification of the semiconductor element;

FIG. 25 is a perspective view illustrating a semiconductor device according to a fourth embodiment;

FIG. 26 is a plan view viewed in a direction along an arrow Z2 in FIG. 25;

FIG. 27 is a cross-section view taken along a line XXVII-XXVII in FIG. 26;

FIG. 28 is a plan view illustrating a circuit pattern of a substrate placed on a drain electrode side and connection structures between semiconductor elements and signal terminals;

FIG. 29 is a plan view illustrating the circuit pattern of the substrate placed on a source electrode side; and

FIG. 30 is a plan view illustrating another modification.

### DETAILED DESCRIPTION

For example, the semiconductor device in JP 2019-176058 A includes two semiconductor elements to which bonding wires are connected. The two semiconductor elements are arranged side by side in a first direction corresponding to a predetermined direction. The plurality of signal terminals connected to the two semiconductor elements are also arranged side by side in the first direction. In such a configuration, a first element and a second element, which correspond to the two semiconductor elements, have structures common to each other, and respective pads on the semiconductor elements to which the bonding wires are to be connected are arranged in the same order in the first direction.

The signal terminals are connected to a circuit substrate formed with a drive circuit for the semiconductor elements. Of the circuit substrate, portions connected to the signal terminals corresponding to the first element, portions connected to the signal terminals corresponding to the second element, and a region between the connected portions become mounting prohibited regions i.e., dead spaces. In the configuration described above, it is difficult to reduce the dead space. From the viewpoint described above or from another viewpoint not mentioned, further improvements are required of the semiconductor device.

The present disclosure provides a semiconductor device which is capable of reducing dead spaces of a circuit substrate.

A semiconductor device according to an aspect of the present disclosure is a semiconductor device to be connected to a circuit substrate. The semiconductor device includes: a plurality of semiconductor elements each having a first main electrode provided on one surface, a second main electrode provided on a back surface opposite to the one surface in a plate thickness direction of the semiconductor element, and a signal pad provided at a location on the back surface different from that of the second main electrode; a wiring member electrically connected to the first main electrode; a plurality of signal terminals connected to the circuit substrate; and bonding wires electrically connecting the pads of the plurality of semiconductor elements and the plurality of signal terminals. In the semiconductor device, each of the plurality of semiconductor elements has a rectangular shape having four corner portions and four side portions in a plan view in the plate thickness direction. The plurality of semiconductor elements include a first element and a second element arranged side by side with the first element in a first direction perpendicular to the plate thickness direction, and the plurality of signal terminals include a plurality of juxtaposed terminals each connected to at least one of the first element and the second element and arranged side by side in the first direction. The plurality of juxtaposed terminals are arranged side by side with the first element and the second element in a second direction perpendicular to each of the plate thickness direction and the first direction. The first element and the second element have structures common to each other and, in each of the first element and the second element, the pads are disposed to offset to a periphery of the first corner portion. In the first element, the first side portion continued to the first corner portion faces the juxtaposed terminals in the second direction, while the second side portion continued to the first corner portion faces the second element in the first direction. The second element is placed in a position resulting from 90-degree rotation from a position of the first element. In the second element, the second side portion continued to the first corner portion faces the juxtaposed terminals in the second direction, while the first side portion continued to the first corner portion faces the first element in the first direction.

In the semiconductor device according to the aspect described above, the first element and the second element, which are arranged side by side in the first direction, have the structures common to each other. In each of the common structures, the pads are provided offset to the periphery the first corner portion which is one of the four corner portions. The first element is placed such that the first side portion which is one of the four side portions faces the juxtaposed terminals in the second direction and that the second side portion faces the second element in the first direction. The second element is placed in a position resulting from the 90-degree rotation from the position of the first element such that the second side portion faces the juxtaposed terminals in the second direction and that the first side portion faces the first element in the first direction. This reduces a length of a pad arrangement region including the pads of the first element and the pads of the second element in the first direction. As a result, it is possible to reduce dead spaces in the circuit substrate to which the signal terminals are connected.

On the basis of the drawings, a plurality of embodiments will be described below. In each of the embodiments, a repetitive description of the corresponding components may be omitted by giving the same reference signs thereto. In each of the embodiments, when only a part of a configuration is described, to another part of the configuration, a configuration in another embodiment previously described is applicable. In addition, not only a combination of configurations explicitly described in the description of each of the embodiments, but also a partial combination of the configurations in the plurality of embodiments can be made even though not explicitly described, as long as the combination has no particular problem.

A semiconductor device in the present embodiment is applied to, e.g., a power conversion device of a movable body using a rotating electrical machine as a drive source. Examples of the movable body include an electric vehicle such as an electrical vehicle (EV), a hybrid vehicle (HV), or a plug-in hybrid vehicle (PHV), a flight vehicle such as a drone, a vessel, a construction machine, and an agricultural machine. A description will be given below of an example in which the semiconductor device is applied to a vehicle.

### First Embodiment

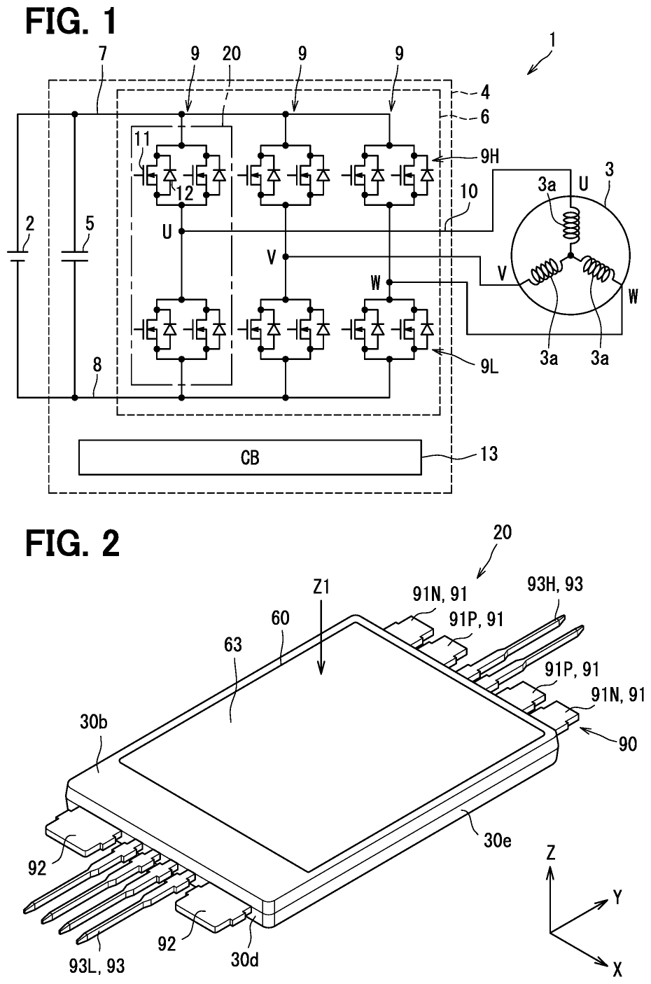

First, referring to FIG. 1, a description will be given of a schematic configuration of a vehicle drive system 1.

### Vehicle Drive System

As illustrated in FIG. 1, the vehicle drive system 1 includes a DC power source 2, a motor generator 3, and a power conversion device 4.

The DC power source 2 is a DC voltage source configured to include a dischargeable secondary battery. Examples of the second battery include a lithium-ion battery and a nickel hydride battery. The motor generator 3 is a 3-phase AC rotating electric machine. The motor generator 3 functions as a travel drive source of the vehicle, i.e., an electric motor. The motor generator 3 functions as a power generator at the time of regeneration. The power conversion device 4 performs power conversion between the DC power source 2 and the motor generator 3.

### Power Conversion Device

Next, referring to FIG. 1, a description will be given of a circuit configuration of the power conversion device 4. The power conversion device 4 includes a power conversion circuit. The power conversion device 4 in the present embodiment includes a smoothing capacitor 5 and an inverter 6 serving as the power conversion circuit.

The smoothing capacitor 5 mainly smoothes a DC voltage supplied from the DC power source 2. The smoothing capacitor 5 is connected to a P-line 8 serving as a high-potential power source line and to an N-line 8 serving as a low-potential power source line. The P-line 7 is connected to a positive electrode of the DC power source 2, while the N-line 8 is connected to a negative electrode of the DC power source 2. The smoothing capacitor 5 has a positive electrode connected to the P-line 7 between the DC power source 2 and the inverter 6. The smoothing capacitor 5 has a negative electrode connected to the N-line 8 between the DC power source 2 and the inverter 6. The smoothing capacitor 5 is connected in parallel to the DC power source 2.

The inverter 6 is a DC-AC conversion circuit. Under switching control of a control circuit not shown, the inverter 6 converts the DC voltage to a 3-phase AC voltage, and outputs the 3-phase AC voltage to the motor generator 3. As a result, the motor generator 3 is driven so as to generate a predetermined torque. At the time of regenerating braking of the vehicle, the inverter 6 converts the 3-phase AC voltage generated by the motor generator 3 on receipt of a rotating force from wheels to a DC voltage under the switching control of the control circuit, and outputs the DC voltage to the P-line 7. Thus, the inverter 6 performs bidirectional power conversion between the DC power source 2 and the motor generator 3.

The inverter 6 is configured to include upper/lower arm circuits 9 corresponding to three phases. The upper/lower arm circuits 9 may be referred to as legs. Each of the upper/lower arm circuits 9 has an upper arm 9H and a lower arm 9L. The upper arms 9H and the lower arms 9L are connected in series between the P-line 7 and the N-line 8 on the assumption that the upper arms 9H are on a P-line 7 side. Connection points between the upper arms 9H and the lower arms 9L are connected to winding wires 3a in corresponding phases in the motor generator 3 via an output line 10. The invertor 6 has six arms. Each of the arms is configured to include a switching element. At least a portion of each of the P-line 7, the N-line 8, and the output line 10 is formed of a conductive material such as, e.g., a bus bar.

In the present embodiment, as the switching element included in each of the arms, an n-channel MOSFET 11 is adopted. The number of the switching elements included in each of the arms is not particularly limited. The number of the switching elements may be one or plural. The MOSFET is an abbreviation of Metal Oxide Semiconductor Field Effect Transistor.

By way of example, in the present embodiment, each of the arms has the two MOSFETs 11. The two MOSFETs 11 included in one of the arms are connected in parallel. In each of the upper arms 9H, respective drains of the two MOSFETs 11 connected in parallel are connected to the P-line 7. In each of the lower arms 9L, respective sources of the two MOSFETs 11 connected in parallel is connected to the N-line 8. Respective sources of the two MOSFETs 11 connected in parallel in the upper arm 9H and respective drains of the two MOSFETs 11 connected in parallel in the lower arm 9L are connected to each other. The two MOSFETs 11 connected in parallel are driven to be turned ON or driven to be turned OFF with the same timing by a common gate drive signal (drive voltage).

To the respective MOSFETs 11, reflux diodes 12 are connected in antiparallel. Each of the diodes 12 may be a parasitic diode (body diode) of the MOSFET 11, or may also be provided separately from the parasitic diode. The diode 12 has an anode connected to the source of the corresponding MOSFET 11, while having a cathode connected to the drain thereof. The upper/lower arm circuit 9 corresponding to one phase is provided by one semiconductor device 20. A description will be given later of details of the semiconductor device 20.

The power conversion device 4 in the present embodiment further includes a circuit substrate 13. The circuit substrate 13 has a substrate comprised of an insulating base material such as a resin in which wiring is placed and electronic components mounted on the substrate. The wiring and the electronic components are included in a circuit. The circuit substrate 13 includes at least a drive circuit for the switching elements included in the inverter 6 or the like. The drive circuit supplies, on the basis of a drive instruction from a control circuit, the drive voltage to a gate of the MOSFET 11 of the corresponding arm. The drive circuit applies the drive voltage to drive the corresponding MOSFET 11, i.e., turn ON or turn OFF the corresponding MOSFET 11. The drive circuit may be referred to also as a driver. For the sake of convenience, in FIG. 1, wiring electrically connecting the circuit substrate 13 and the gate of the MOSFET 11 is omitted.

The circuit substrate 13 may also further include the control circuit for the switching elements. The control circuit may also be provided separately from the circuit substrate 13 including the drive circuit. The control circuit generates the drive instruction for operating the MOSFETs 11, and outputs the drive instruction to the drive circuit. The control circuit generates the drive instruction on the basis of, e.g., a torque request input from a higher-level ECU not shown or signals detected by various sensors. The ECU is an abbreviation of Electronic Control Unit.

For example, the various sensors are a current sensor, a rotation angle sensor, and a voltage sensor. The current sensor detects a phase current flowing in the winding wire 3a in each of phases. The rotation angle sensor detects a rotation angle of a rotor of the motor generator 3. The voltage sensor detects a voltage between both ends of the smoothing capacitor 5. The control circuit outputs, e.g., a PWM signal as the drive instruction. The control circuit is configured to include, e.g., a processor and a memory. The PWM is an abbreviation of Pulse Width Modulation.

The power conversion device 4 may also further include a converter as the power conversion circuit. The converter is a DC-DC conversion circuit that converts a DC voltage to a DC voltage having a different value. The converter is provided between the DC power source 2 and the smoothing capacitor 5. The converter is configured to include, e.g., a reactor and the upper/lower arm circuits 9 described above. This configuration allows voltage step-up and step-down. The power conversion device 4 may also include a filter capacitor that removes power source noise from the DC power source 2. The filter capacitor is provided between the DC power source 2 and the converter.

### Semiconductor Device

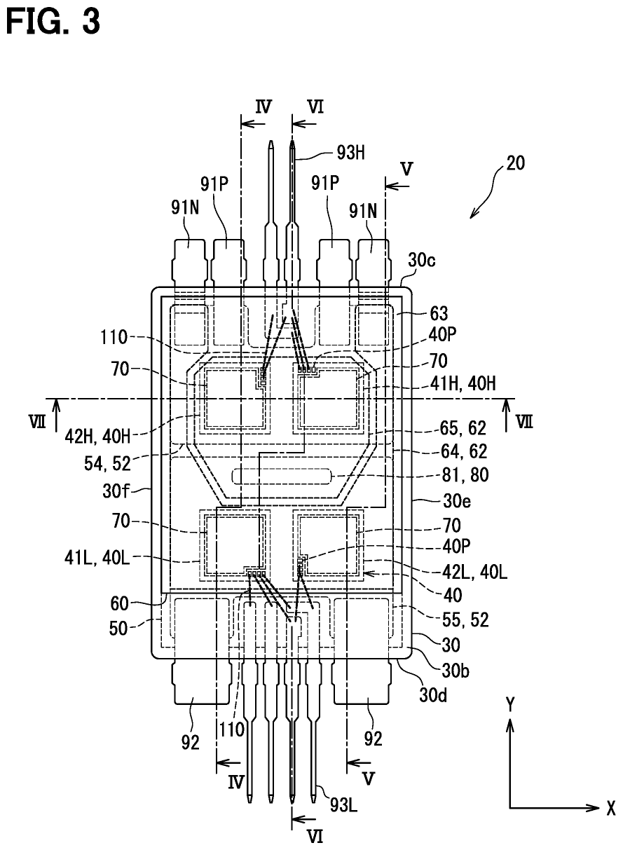

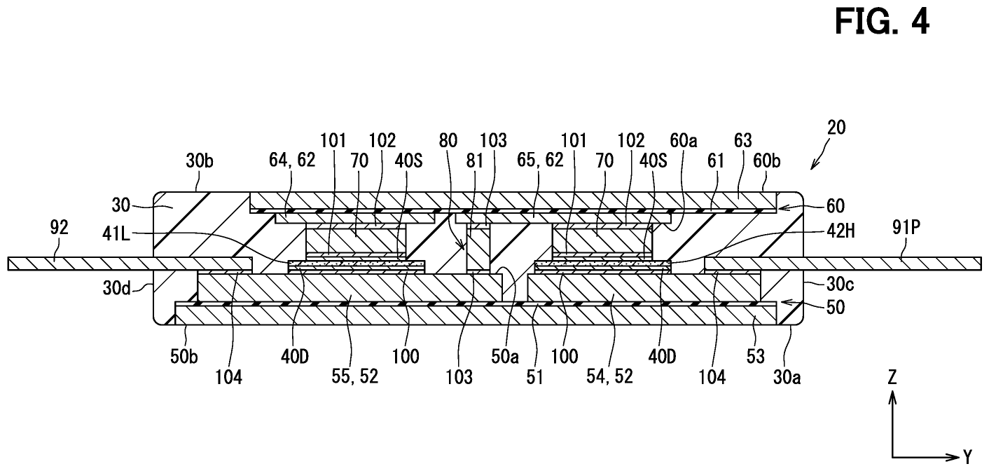

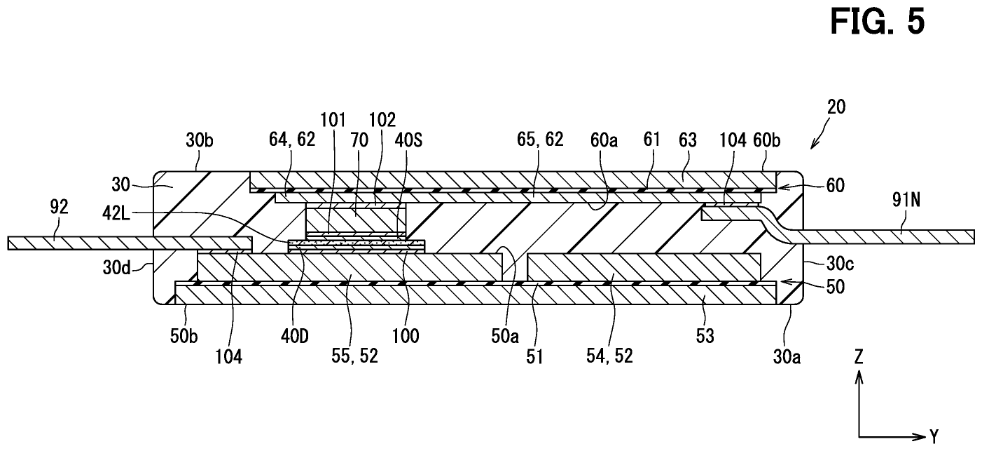

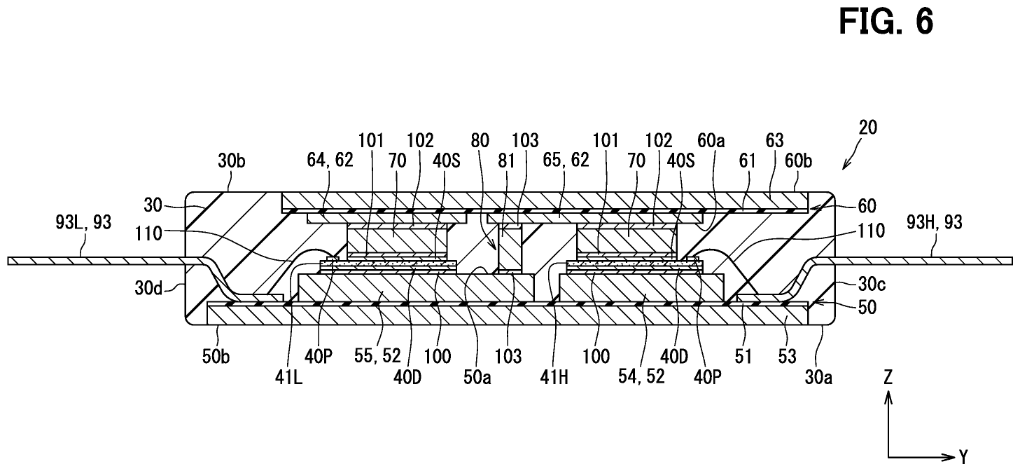

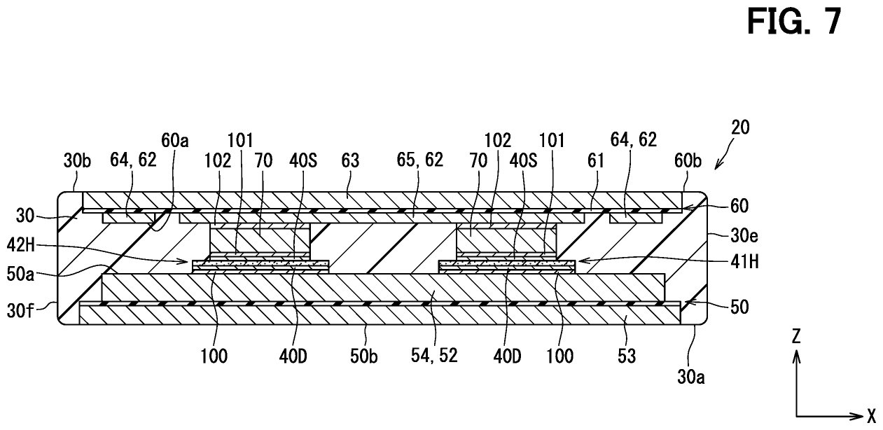

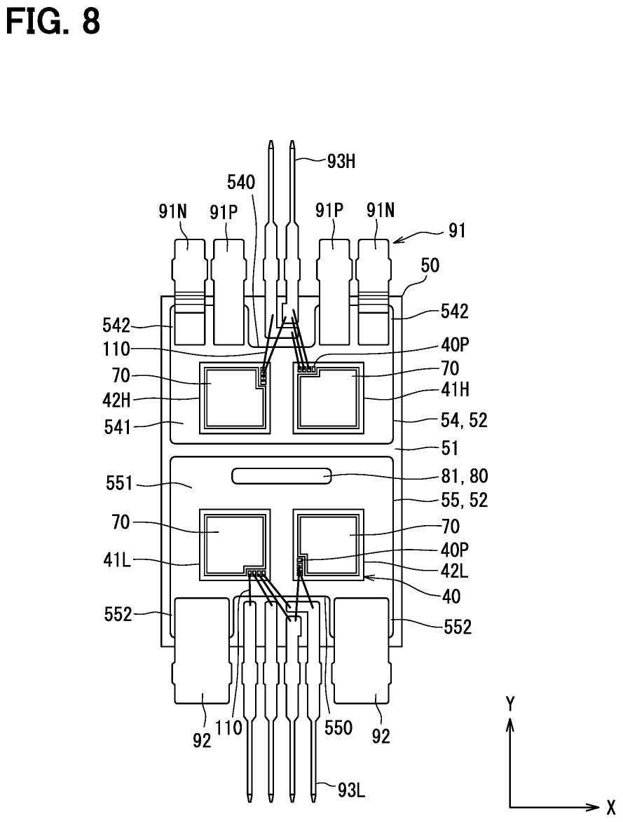

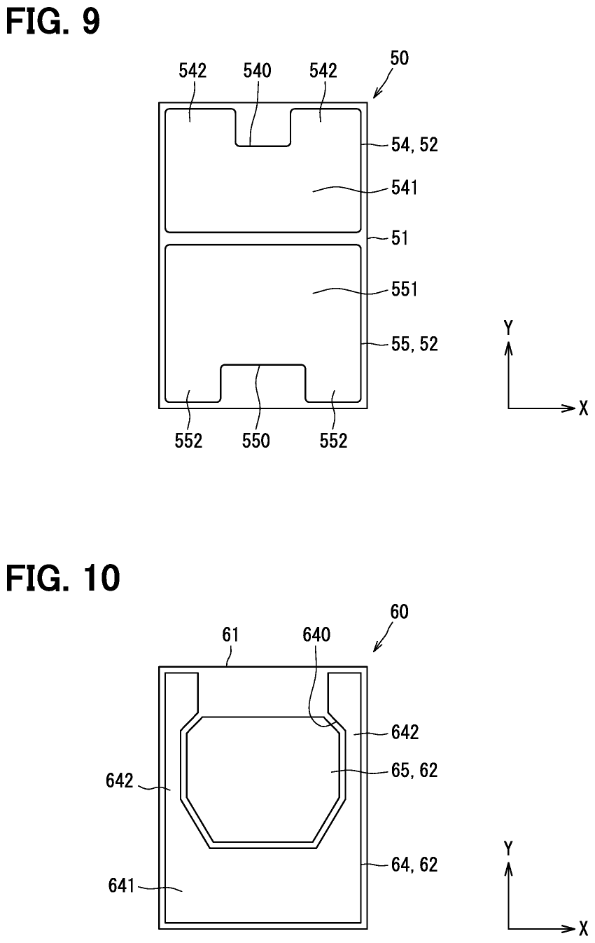

Next, on the basis of FIGS. 2 to 10, a description will be given of the semiconductor device. FIG. 2 is a perspective view of the semiconductor device 20. FIG. 3 is a plan view obtained by viewing FIG. 2 from a Z1 direction. FIG. 3 is a transparent view illustrating an inner structure. FIG. 4 is a cross-sectional view along a line IV-IV in FIG. 3. FIG. 5 is a cross-sectional view along a line V-V in FIG. 3. FIG. 6 is a cross-sectional view along a line VI-VI in FIG. 3. FIG. 7 is a cross-sectional view along a line VII-VII in FIG. 3. FIG. 8 is a plan view illustrating a state where semiconductor elements 40 are mounted on a substrate 50. FIG. 8 is a diagram obtained by removing a sealing body 30 and a substrate 60 from FIG. 3. FIG. 9 is a plan view illustrating a circuit pattern of a top surface metal body 52 on the substrate 50. FIG. 10 is a plan view illustrating a circuit pattern of a top surface metal body 62 on the substrate 60.

In the following, it is assumed that a plate thickness direction of the semiconductor elements 40 (semiconductor substrate) is a Z-direction. It is assumed that a direction which is perpendicular to the Z-direction and in which the plurality of semiconductor elements 40 are arranged side by side with each other is an X-direction. In the present embodiment, the direction in which the plurality of semiconductor elements 40 connected in parallel are arranged is assumed to be the X-direction. It is assumed that a direction perpendicular to both of the Z-direction and the X-direction is a Y-direction. Unless otherwise specified, a shape viewed in a plan view from the Z-direction, i.e., a shape along an XY-plane prescribed by the X-direction and the Y-direction is a planar shape. The plan view from the Z-direction may be referred to simply as plan view. In addition, an arrangement is not limited to that over a mounting surface, and an overlapping relationship in the plan view may also be referred to as an arrangement. The X-direction corresponds to a first direction, while the Y-direction corresponds to a second direction.

As illustrated in FIGS. 2 to 10, the semiconductor device 20 forms one of the upper/lower arm circuits 9 described above, i.e., the upper/lower arm circuit 9 corresponding to one phase. The semiconductor device 20 includes the sealing body 30, the semiconductor elements 40, the substrates 50 and 60, conductive spacers 70, an arm connection portion 80, and external connection terminals 90. The semiconductor device 20 may be referred to also as a semiconductor module or a power card.

The sealing body 30 seals a portion of each of other components included in the semiconductor device 20. The remaining portions of the other components are exposed to the outside of the sealing body 30. Examples of a material of the sealing body 30 include a resin. Examples of the resin include an epoxy resin. The sealing body 30 is molded using a resin as a material by, e.g., a transfer mold method. The sealing body 30 thus molded may be referred to as a sealing resin body, a mold resin, or a resin molded body. The sealing body 30 may also be formed using, e.g., a gel. The gel fills (is placed in), e.g., respective facing regions of the pair of the substrates 50 and 60.

As illustrated in FIGS. 2 to 4, the sealing body 30 has a substantially rectangular planar shape. The sealing body 30 has, as surfaces forming an outline thereof, one surface 30a and a back surface 30b opposite to the one surface 30a in the Z-direction. For example, the one surface 30a and the back surface 30b are planar surfaces. The sealing body 30 also has side surfaces 30c, 30d, 30e, and 30f serving as surfaces connecting the one surface 30a and the back surface 30b. The side surface 30c is a surface from which power source terminals 91 and signal terminals 93H which are included in the external connection terminals 90 protrude. The side surface 30d is a surface opposite to the side surface 30c in the Y-direction. The side surface 30d is a surface from which output terminals 92 and signal terminals 93L protrude. The side surfaces 30e and 30f are surfaces from which none of the external connection terminals 90 protrudes. The side surface 30e is a surface opposite to the side surface 30f in the X-direction.

Each of the semiconductor elements 40 is comprised of the switching elements formed on a semiconductor substrate made of a material such as silicon (Si), a wide-bandgap semiconductor having a bandgap wider than that of the silicon, or the like. Examples of the wide-bandgap semiconductor include a silicon carbide (SiC), a gallium nitride (GaN), a gallium oxide (Ga₂O₃), diamond, and the like. The semiconductor element 40 may be referred to also as a power element or a semiconductor chip.

Each of the semiconductor elements 40 in the present embodiment includes the n-channel MOSFETs 11 described above, which are formed in the semiconductor substrate made of SiC serving as a material. Each of the MOSFETs 11 has a vertical structure so as to allow a main current to flow in the plate thickness direction of the semiconductor element 40 (semiconductor substrate), i.e., in the Z-direction. The semiconductor element 40 has main electrodes of the switching element on both surfaces thereof in the Z-direction corresponding to the plate thickness direction thereof. Specifically, each of the semiconductor elements 40 has, as the main electrodes, a drain electrode 40D on one surface and a source electrode 40S on a back surface corresponding to a surface opposite to the one surface in the Z-direction. The main current flows between the drain electrode 40D and the source electrode 40S.

When the diode 12 is a parasitic diode, the source electrode 40S serves also as an anode electrode, while the drain electrode 40D serves also as a cathode electrode. The diode 12 may also be configured in a chip other than that of the MOSFET 11. The drain electrode 40D is a high-potential main electrode, while the source electrode 40S is a low-potential main electrode.

The semiconductor element 40 has a substantially rectangular planar shape, e.g., a square shape. As illustrated in FIGS. 3 and 8, the semiconductor element 40 has, on the back surface, pads 40P as signal electrodes. The pads 40P are electrically isolated from the source electrode 40S. The pads 40P are formed at locations different from that of the source electrode 40S on the back surface. The pads 40P include at least a gate electrode pad. The semiconductor element 40 in the present embodiment has the four pads 40P.

The source electrode 40S and the pads 40P are exposed from a protection film formed on the back surface of the semiconductor substrate and not shown. The drain electrode 40D is formed substantially entirely over the one surface. The source electrode 40S is formed on a portion of the back surface of the semiconductor element 40. In the plan view, the drain electrode 40D occupies an area larger than that occupied by the source electrode 40S. The drain electrode 40D corresponds to a first main electrode, while the source electrode 40S corresponds to a second main electrode.

The semiconductor device 20 includes a plurality of the semiconductor elements 40 each having the configuration described above. The plurality of semiconductor elements 40 include semiconductor elements 40H included in the upper arms 9H and semiconductor elements 40L included in the lower arms 9L. The semiconductor elements 40H may be referred to also as upper arm elements, while the semiconductor elements 40L may be referred to also as lower arm elements. The semiconductor elements 40 in the present embodiment include the two semiconductor elements 40H and the two semiconductor elements 40L.

The semiconductor elements 40H include a semiconductor element 41H corresponding to a first element and a semiconductor element 42H corresponding to a second element. The two semiconductor elements 40H (41H, 42H) are arranged in the X-direction. The two semiconductor elements 40H arranged side by side in the X-direction have structures common to each other. The two semiconductor elements 40H are connected in parallel to each other.

The semiconductor elements 40L include a semiconductor element 41L corresponding to a first element and a semiconductor element 42L corresponding to a second element. The two semiconductor elements 40L (41L, 42L) are arranged in the X-direction. The two semiconductor elements 40L arranged side by side in the X-direction have structures common to each other. The two semiconductor elements 40L are connected in parallel to each other.

In the present embodiment, all the semiconductor elements 40 have structures common to each other. An arrangement of the semiconductor elements 41H and 42H and an arrangement of the semiconductor the semiconductor elements 41L and 42L have two-fold symmetry around an axis along the Z-direction. The semiconductor elements 40H and the semiconductor elements 40L are arranged in the Y-direction. The semiconductor device 20 has two columns including the semiconductor elements 40H and the semiconductor elements 40L along the Y-direction. The X-direction is the first direction perpendicular to the plate thickness direction (Z-direction) of the semiconductor elements 40. The Y-direction is the second direction perpendicular to each of the plate thickness direction and the first direction.

The individual semiconductor elements 40 are placed at locations substantially equal to each other in the Z-direction. The individual semiconductor elements 40 have the respective drain electrodes 40D facing the substrate 50. The individual semiconductor elements 40 have the respective source electrodes 40S facing the substrate 60. A description will be given later of details of the semiconductor elements 40 including the pads 40P and an arrangement thereof.

The substrates 50 and 60 are arranged in the Z-direction so as to have the plurality of semiconductor elements 40 interposed therebetween. The substrates 50 and 60 are arranged so as to have at least respective portions thereof facing each other in the Z-direction. The substrates 50 and 60 include all of the plurality of semiconductor elements 40 (40H and 40L) in the plan view.

The substrate 50 is disposed on a drain electrode 40D side of each of the semiconductor elements 40. The substrate 60 is disposed on a source electrode 40S side of each of the semiconductor elements 40. As described later, the substrate 50 is electrically connected to the drain electrodes 40D to provide a wiring function. Likewise, the substrate 60 is electrically connected to the source electrodes 40S to provide a wiring function. Accordingly, the substrates 50 and 60 may be referred to also as wiring members or wiring substrates. The substrate 50 may be referred to also as a drain substrate, while the substrate 60 may be referred to also as a source substrate. The substrates 50 and 60 provide a heat dissipating function of dissipating heat generated in the semiconductor elements 40. Accordingly, the substrates 50 and 60 may be referred to also as heat dissipating members. The substrate 50 corresponds to a wiring member electrically connected to the first main electrode.

The substrate 50 has a facing surface 50a facing the semiconductor elements 40 and a back surface 50b corresponding to a surface opposite to the facing surface 50a. The substrate 50 includes an insulating base material 51, the top surface metal body 52, and a back surface metal body 53. The substrate 50 is a substate in which the insulating base material 51 and the metal bodies 52 and 53 are stacked. The substrate 60 has a facing surface 60a facing the semiconductor elements 40 and a back surface 60b corresponding to a surface opposite to the facing surface 60a. The substrate 60 includes an insulating base material 61, the top surface metal body 62, and a back surface metal body 63. The substrate 60 is a substrate in which the insulating base material 61 and the metal bodies 62 and 63 are stacked. In the following, the top surface metal bodies 52 and 62 and the back surface metal bodies 53 and 63 may be referred to simply as the metal bodies 52, 53, 62, and 63.

The insulating base material 51 electrically isolates the top surface metal body 52 and the back surface metal body 53 from each other. Likewise, the insulating base material 61 electrically isolates the top surface metal body 62 and the back surface metal body 63 from each other. The insulating base materials 51 and 61 may be referred to also as insulating layers. A material of the insulating base materials 51 and 61 is a resin or an inorganic material ceramic. As the resin, e.g., an epoxy resin, a polyimide resin, or the like can be used. As the ceramic, e.g., Al₂O₃ (alumina), Si₃N₄ (silicon nitride), or the like can be used. When the insulating base materials 51 and 61 are made of the resin, the substrates 50 and 60 may be referred to also as metal resin substrates. When the insulating base materials 51 and 61 are made of the ceramic, the substrates 50 and 60 may be referred to also as metal ceramic substrates.

In the case of the insulating base materials 51 and 61 using a resin material, to improve a heat dissipating property, an insulating property, or the like, an inorganic filler (inorganic filling material) may also be included in the resin. It may also be possible to adjust a linear expansion coefficient by adding the filler. As the filler, e.g., Al₂O₃, SiO₂ (silicon dioxide), AlN (aluminum nitride), BN (boron nitride), or the like can be used. Each of the insulating base materials 51 and 61 may include only one type of filler or a plurality of types of fillers.

When consideration is given to the heat dissipating property and the insulating property, in the case of a resin type, respective thicknesses, i.e., lengths in the Z-direction of the insulating base materials 51 and 61 are preferably about 50 μm to 300 μm. In the case of a ceramic type, the thicknesses of the insulating base materials 51 and 61 are preferably about 200 μm to 500 μm. In the Z-direction, surfaces of the insulating base materials 51 and 61 are inner surfaces, e.g., surfaces on a semiconductor element 40 side, while back surfaces thereof corresponding to surfaces opposite to the surfaces are outer surfaces. The insulating base materials 51 and 61 may have either a common (the same) material composition or different material compositions. In the present embodiment, the resin-based insulating base materials 51 and 61 are adopted, and the material compositions are common. By adding the filler to the resin, the linear expansion coefficients of the insulating base materials 51 and 61 are adjusted to substantially the same value as that of the sealing body 30. By adding the filler to the resin, the respective linear expansion coefficients of the insulating base materials 51 and 61 and the sealing body 30 have values close to that of a metal (Cu) forming the metal bodies 52, 53, 62, and 63.

The metal bodies 52, 53, 62, and 63 are provided as, e.g., metal plates or metal foil. The metal bodies 52, 53, 62, and 63 are formed using, as a material, a metal having excellent electric and thermal conductivities, such as Cu or Al. Respective thicknesses of the metal bodies 52, 53, 62, and 63 are, e.g., about 0.1 mm to 3 mm. The top surface metal body 52 is placed on the surface of the insulating base material 51 in the Z-direction. The back surface metal body 53 is placed on the back surface of the insulating base material 51. Likewise, the top surface metal body 62 is placed on the surface of the insulating base material 61 in the Z-direction. The back surface metal body 63 is placed on the back surface of the insulating base material 61.

Relationships between the thicknesses of the top surface metal bodies 52 and 62 and those of the back surface metal bodies 53 and 63 are not particularly limited. The thickness of the top surface metal body 52 may be set larger than that of the back surface metal body 53 or may also be set substantially equal to that of the back surface metal body 53. It may also be possible to set the thickness of the top surface metal body 52 smaller than that of the back surface metal body 53. Likewise, the thickness of the top surface metal body 62 may be set larger than that of the back surface metal body 63 or may also be set substantially equal to that of the back surface metal body 63. It may also be possible to set the thickness of the top surface metal body 62 smaller than that of the back surface metal body 63. A relationship between the thicknesses of the top surface metal bodies 52 and 62 is also not particularly limited, and a relationship between the thicknesses of the back surface metal bodies 53 and 63 is also not particularly limited.

The top surface metal bodies 52 and 62 are patterned. Each of the top surface metal bodies 52 and 62 provides wiring, i.e., a circuit. Accordingly, each of the top surface metal bodies 52 and 62 may be referred to also as a circuit pattern, a wiring layer, or a circuit conductor. Each of the top surface metal bodies 52 and 62 may also include a plating film of a Ni type, Au, or the like. In the following, patterns of the top surface metal bodies 52 and 62 may be referred to also as circuit patterns. A surface of the top surface metal body 52 and a region of the surface of the insulating base material 51 where the top surface metal body 52 is not placed form the facing surface 50a of the substrate 50. Likewise, a surface of the top surface metal body 62 and a region of the surface of the insulating base material 61 where the top surface metal body 62 is not placed form the facing surface 60a of the substrate 60.

For example, the substrates 50 and 60 may also be formed by preparing the top surface metal bodies 52 and 62 each patterned into a predetermined shape by, e.g., press working, etching, or the like and adhering the patterned top surface metal bodies 52 and 62 to a layered body having a two-layered structure including the insulating base materials 51 and 61 and the back surface metal bodies 53 and 63. It may also be possible to form a layered body having a three-layered structure including the top surface metal bodies 52 and 62, the insulating base materials 51 and 61, and the back surface metal bodies 53 and 63 and then pattern the top surface metal bodies 52 and 62 by cutting or etching.

As illustrated in FIGS. 8 and 9, the top surface metal body 52 has P-wiring 54 and relay wiring 55. The P-wiring 54 and the relay wiring 55 are electrically isolated from each other by a predetermined space (gap). The gap is filled with the sealing body 30.

The P-wiring 54 is connected to each of P-terminals 91P described layer and the drain electrodes 40D of the semiconductor elements 40H. The P-wiring 54 electrically connects the P-terminals 91P and the drain electrodes 40D of the semiconductor elements 40H. The P-wiring 54 electrically connects the drain electrode 40D of the semiconductor element 41H and the drain electrode 40D of the semiconductor element 42H. The P-wiring 54 may be referred to also as positive electrode wiring or high-potential power source wiring.

The relay wiring 55 is connected to each of the drain electrodes 40D of the semiconductor elements 40L, the arm connection portion 80, and the output terminals 92. The relay wiring 55 electrically connects the arm connection portion 80 and the drain electrodes 40D of the semiconductor elements 40H. The relay wiring 55 electrically connects each of the source electrodes 40S of the semiconductor elements 40H and the drain electrodes of the semiconductor elements 40L to the output terminals 92. The relay wiring 55 electrically connects the drain electrode 40D of the semiconductor element 41L and the drain electrode 40D of the semiconductor element 42L.

The P-wiring 54 and the relay wiring 55 are arranged side by side in the Y-direction. In the Y-direction, the P-wiring 54 is placed on a power source terminal 91 side, while the relay wiring 55 is placed on an output terminal 92 side. In other words, the P-wiring 54 is placed on a side surface 30c side of the sealing body 30, while the relay wiring 55 is placed on a side surface 30d side thereof.

The P-wring 54 has a notch 540. The notch 540 is opened in one of four sides of a substantially rectangular planar shape having the X-direction as a longitudinal direction. The notch 540 is provided substantially at a middle of the side facing the side surface 30c in the X-direction. The P-wiring 54 has a base portion 541 and a pair of extending portions 542. The base portion 541 and the pair of extending portions 542 define the notch 540. The P-wiring 54 has a substantially letter-U (depressed) planar shape.

The base portion 541 is a portion on a relay wiring 55 side of each of the notch 540 and the extending portions 542, and has a substantially rectangular planar shape. The base portion 541 overlaps the semiconductor elements 40H in the plan view. In other words, the two semiconductor elements 40H (41H and 42H) are placed in the base portion 541. The semiconductor elements 40H have the respective drain electrodes 40D connected to the base portion 541.

The two extending portions 542 extend from the base portion 541 in the same direction, specifically in the Y-direction and on the side surface 30c side of the sealing body 30. One of the extending portions 542 is continued to the vicinity of one end of the base portion 541 in the X-direction, while another thereof is continued to the vicinity of another end of the base portion 541. Both end portions of the letter U of the P-wiring 54, i.e., end portions of the two extending portions 542 opposite to the base portion 541 are at substantially the same location in the Y-direction. The pair of extending portions 542 have the notch 540 interposed therebetween in the X-direction. The base portion 541 has a length in the Y-direction which is larger than each of a depth of the notch 540 and lengths of the extending portions 542.

The relay wiring 55 also has a notch 550. The notch 550 is opened in one of four sides of a substantially rectangular planar shape. The notch 550 is provided substantially at a middle of the side facing the side surface 30d in the X-direction. In other words, in one of end portions of the top surface metal body 52 in the Y-direction, the notch 540 is provided, while the notch 550 is provided in another of the end portions.

The relay wiring 55 has a base portion 551 and a pair of extending portions 552. The base portion 551 and the pair of extending portions 552 define the notch 550. The relay wiring 55 has a substantially letter-U (depressed) planar shape. The base portion 551 is a portion on a P-wiring 54 side of each of the notch 550 and the extending portions 552 in the Y-direction, and has a substantially rectangular planar shape. The base portion 551 overlaps the semiconductor elements 40L in the plan view. In other words, the two semiconductor elements 40L (41L and 42L) are placed in the base portion 551. The semiconductor elements 40L have the respective drain electrodes 40D connected to the base portion 551.

The two extending portions 552 extend from the base portion 551 in the same direction, specifically in the Y-direction and on the side surface 30d side of the sealing body 30. One of the extending portions 552 is continued to the vicinity of one end of the base portion 551 in the X-direction, while another thereof is continued to the vicinity of another end of the base portion 551. Both end portions of the letter U of the relay wiring 55, i.e., end portions of the two extending portions 552 opposite to the base portion 551 are at substantially the same location in the Y-direction. The pair of extending portions 552 have the notch 550 interposed therebetween in the X-direction. The base portion 551 has a length in the Y-direction which is larger than a depth of the notch 550 and lengths of the extending portions 552.

On the other hand, as illustrated in FIGS. 3 and 10, the top surface metal body 62 has N-wiring 64 and relay wiring 65. The N-wiring 64 and the relay wiring 65 are electrically isolated from each other by a predetermined space (gap). The gap is filled with the sealing body 30.

The N-wiring 64 is connected to each of N-terminals 91N described later and the source electrodes 40S of the semiconductor elements 40L. The N-wiring 64 electrically connects the N-terminals 91N and the source electrodes 40S of the semiconductor elements 40L. The N-wiring 64 electrically connects the source electrode 40S of the semiconductor element 41L and the source electrode 40S of the semiconductor element 42L. The N-wiring 64 may be referred to also as negative electrode wiring or low-potential power source wiring.

The relay wiring 65 is connected to each of the source electrodes 40S of the semiconductor elements 40H and the arm connection portion 80. The relay wiring 65 electrically connects the source electrodes 40S of the semiconductor elements 40H and the arm connection portion 80. The relay wiring 65 electrically connects the source electrode 40S of the semiconductor element 41H and the source electrode 40S of the semiconductor element 42H.

The N-wiring 64 also has a notch 640. The notch 640 is opened in one of four sides of a substantially rectangular planar shape. The notch 640 is provided at substantially a middle in the X-direction in the side facing the side surface 30c. The N-wiring 64 has a base portion 641 and a pair of extending portions 642. The base portion 641 and the pair of extending portions 642 define the notch 640. The N-wiring 64 has a substantially letter-U (depressed) planar shape.

The base portion 641 is a portion on the side surface 30d side of each of the notch 640 and the extending portions 642. The base portion 641 has a substantially rectangular planar shape having the X-direction as a longitudinal direction. The base portion 641 is arranged side by side with the relay wiring 65 in the Y-direction. The base portion 641 overlaps the semiconductor elements 40L in the plan view. In other words, the two semiconductor elements 40L (41L and 42L) are placed in the base portion 641. The semiconductor elements 40L have the respective source electrodes 40S connected to the base portion 641.

The two extending portions 642 extend from the base portion 641 in the same direction, specifically in the Y-direction and on the side surface 30c side of the sealing body 30. One of the extending portions 642 is continued to the vicinity of one end of the base portion 641 in the X-direction, while another thereof is continued to the vicinity of another end of the base portion 641. Both end portions of the letter U of the N-wiring 64, i.e., end portions of the two extending portions 642 opposite to the base portion 641 are at substantially the same location in the Y-direction.

The pair of extending portions 642 serve as both ends of the top surface metal body 62 in the X-direction. The pair of extending portions 642 are arranged in the vicinities of the end portions of the substrate 60. In the plan view, the pair of extending portions 642 have respective portion overlapping the P-wiring 54. In the Y-direction, the extending portions 642 have lengths larger than that of the base portion 641.

As described above, the relay wiring 65 is arranged side by side with the N-wiring 64, specifically the bae portion 641 in the Y-direction. In the Y-direction, the relay wiring 65 is placed at a location close to the side surface 30c of the sealing body 30, while the base portion 641 is placed at a location close to the side surface 30d. The relay wiring 65 is interposed between the pair of extending portions 642 in the X-direction. The relay wiring 65 is interposed between the pair of extending portions 642. The relay wiring 65 is placed in the notch 640. The relay wiring 65 is placed to have a predetermined space (gap) with the N-wiring 64. In the plan view, the relay wiring 65 has a portion overlapping the P-wiring 54, while having another portion overlapping the relay wiring 55.

The relay wiring 65 overlaps the semiconductor elements 40H in the plan view. In other word, the two semiconductor elements 40H (41H and 42H) are placed on the relay wiring 65. The semiconductor elements 40H have the respective source electrodes 40S connected to the relay wiring 65.

The back surface metal bodies 53 and 63 are electrically isolated by the insulating base materials 51 and 61 from a circuit including the semiconductor elements 40 and the top surface metal bodies 52 and 62. The back surface metal bodies 53 and 63 may be referred to also as metal base substrates. Heat generated in the semiconductor elements 40 is transferred to the back surface metal bodies 53 and 63 via each of the top surface metal bodies 52 and 62 and the insulating base materials 51 and 61. The back surface metal bodies 53 and 63 provide the heat dissipating function.

The back surface metal bodies 53 and 63 in the present embodiment have substantially rectangular planar shapes, and outlines thereof substantially match respective outlines of the top surface metal bodies 52 and 62. The back surface metal bodies 53 and 63 are so-called solid conductors placed over substantially the entire regions of the back surfaces of the insulating base materials 51 and 61. As described above, since the linear expansion coefficients of the insulating base materials 51 and 61 are adjusted by adding the filler, even when top and back patterns are made different, it is possible to inhibit warping. Needless to say, the back surface metal bodies 53 and 63 may also be patterned so as to match the top surface metal bodies 52 and 62 in the plan view.

The back surface metal bodies 53 and 63 in the present embodiment are placed over substantially the entire regions of the back surfaces of the corresponding insulating base materials 51 and 61. To further enhance a heat dissipating effect, at least one of the back surface metal bodies 53 and 63 may also be exposed from the sealing body 30. In the present embodiment, the back surface metal body 53 is exposed from the one surface 30a of the sealing body 30, while the back surface metal body 63 is exposed from the back surface 30b. The exposed surface of the back surface metal body 53 is substantially flush with the one surface 30a. The exposed surface of the back surface metal body 63 is substantially flush with the back surface 30b. The back surface metal bodies 53 and 63 form the back surfaces 50b and 60b of the substrates 50 and 60.

The conductive spacers 70 provide a spacer function of ensuring a predetermined space between each of the semiconductor elements 40 and the substrate 60. For example, the conductive spacers 70 ensure, to the pads 40P of the semiconductor elements 40, a height for electrically connecting corresponding signal terminals 93. The conductive spacers 70 are located midway in an electric/thermal conduction path between the source electrodes 40S of the semiconductor elements 40 and the substrate 60 to provide a wiring function and the heat dissipating function. The conductive spacers 70 contain a metal material with excellent electric/thermal conductivities, such as Cu. Each of the conductive spacers 70 may also include a plating film on a surface thereof.

The conductive spacers 70 may be referred to also as terminals, terminal blocks, or metal block bodies. The semiconductor device 20 includes the same number of the conductive spacers 70 as that of the semiconductor elements 40. Specifically, the four conductive spacers 70 are included. The conductive spacers 70 are individually connected to the semiconductor elements 40. In the plan view, each of the conductive spacers 70 is a prismatic body having substantially the same size as that of the source electrode 40S.

The arm connection portion 80 electrically connects the relay wiring 55 and the relay wiring 65. In other words, the arm connection portion 80 electrically connects the upper arm 9H and the lower arm 9L. The arm connection portion 80 is provided between the semiconductor elements 40H and the semiconductor elements 40L in the Y-direction. The arm connection portion 80 is provided in a region where the relay wiring 55 and the relay wiring 65 overlap each other in the plan view. The arm connection portion 80 in the present embodiment includes a joint portion 81 and joining materials 103 described later.

The joint portion 81 is a metal prismatic body provided separately from the top surface metal bodies 52 and 62. The joint portion 81 thus provided may be referred to also as a joint terminal. In the Z-direction, between one of end portions of the joint portion 81 and the relay wiring 55, the joining material 103 is interposed and, between another of the end portions and the relay wiring 65, the joining material 103 is interposed.

Alternatively, the joint portion 81 may also be integrally continued to at least one of the top surface metal bodies 52 and 62. In other words, the joint portion 81 may also be integrally provided with either of the top surface metal bodies 52 and 62 to form a portion of either of the substrates 50 and 60. For example, the joint portion 81 is a protruding portion of the top surface metal body 62 (relay wiring 65). The arm connection portion 80 may also be configured not to include the joint portion 81. In other words, the arm connection portion 80 may also be configured to include only the joining materials 103.

The external connection terminals 90 are terminals for electrically connecting the semiconductor device 20 to an external device. The external connection terminals 90 are formed using a metal material having an excellent conductivity, such as copper. For example, each of the external connection terminals 90 is a plate material. The external connection terminals 90 may be referred to also as leads. The external connection terminals 90 include the power source terminals 91, the output terminals 92, and the signal terminals 93. The power source terminals 91 include the P-terminals 91P and the N-terminals 91N. The P-terminals 91P, the N-term inals 91N, and the output terminals 92 are main terminals electrically connected to the main electrodes of the semiconductor elements 40. The signal terminals 93 include the signal terminals 93H on an upper arm 9H side and the signal terminals 93L on a lower arm 9L side.

The power source terminals 91 are the external connection terminals 90 electrically connected to the power source lines 7 and 8 described above. The P-term inals 91P are electrically connected to a positive electrode terminal of the smoothing capacitor 5. Each of the P-terminals 91P may be referred to also as a positive electrode terminal or a high-potential power source terminal. The P-terminals 91P are connected to the P-wiring 54 of the top surface metal body 52. In other words, the P-terminals 91P are connected to the drain electrodes 40D of the semiconductor elements 40H included in the upper arms 9H.

Each of the P-terminals 91P is connected to the vicinity of one end of the P-wiring 54 in the Y-direction. The P-terminals 91P extend in the Y-direction from connection portions (junction portions) with the P-wiring 54 to protrude from the vicinity of a middle of the side surface 30c in the Z-direction to the outside of the sealing body 30. The semiconductor device 20 in the present embodiment includes the two P-term inals 91P. As illustrated in FIG. 8, one of the P-terminals 91P is connected to one of the pair of extending portions 542, while another thereof is connected to another of the pair of extending portions 542. The P-terminals 91P are placed at respective positions on the extending portions 542 closer to the notch 540 so as to be adjacent to the N-terminals 91N in the plan view, i.e., placed inward. The two P-terminals 91P are arranged side by side in the X-direction. The two P-terminals 91P are placed at substantially the same location in the Z-direction.

The N-terminals 91N are electrically connected to a negative electrode terminal of the smoothing capacitor 5. Each of the N-terminals 91N may be referred to also as a negative electrode terminal or a low-potential power source terminal. The N-terminals 91N are connected to the N-wiring 64 of the top surface metal body 62. In other words, the N-terminals 91N are connected to the source electrodes 40S of the semiconductor elements 40L included in the lower arms 9L.

Each of the N-terminals 91N is connected to the vicinity of one end of the N-wiring 64 in the Y-direction. The N-terminals 91N extend in the Y-direction from junction portions with the N-wiring 64 to protrude from the vicinity of the middle of the side surface 30c in the Z-direction to the outside of the sealing body 30. The semiconductor device 20 includes the two N-terminals 91N. One of the N-terminals 91N is connected to one of the pair of extending portions 642, while another thereof is connected to another of the pair of extending portions 642. The two N-terminals 91N are arranged side by side in the X-direction. The two N-terminals 91N are placed at substantially the same location in the Z-direction.

The two N-terminals 91N are placed outside the two P-terminals 91P in the X-direction. In the plan view, one of the N-terminals 91N is placed in the vicinity of one of the P-terminals 91P, while another of the N-terminals 91N is placed in the vicinity of another of the P-terminals 91P. The N-terminals 91N and the P-terminals 91P adjacent to each other in the X-direction have respective side surface thereof facing each other at respective parts thereof including portions protruding from the sealing body 30.

The output terminals 92 are electrically connected to the winding wires 3a (stator coils) in the corresponding phases in the motor generator 3. Each of the output terminals 92 may be referred to also as an O-terminal, an AC terminal, or the like. As illustrated in FIGS. 3 and 8, the output terminals 92 are connected to the relay wiring 55 of the top surface metal body 52 of the substrate 50. In other words, the output terminals 92 are connected to connection points between the upper arms 9H and the lower arms 9L.

Each of the output terminals 92 is connected to the vicinity of one end of the relay wiring 55 in the Y-direction. The output terminals 92 extend from junction portions with the relay wiring 55 in the Y-direction to protrude from the vicinity of a middle of the side surface 30d in the Z-direction to the outside of the sealing body 30. The semiconductor device 20 includes the two output terminals 92. One of the output terminals 92 is connected to one of the pair of extending portions 552, while another thereof is connected to another of the pair of extending portions 552. The two output terminals 92 are arranged side by side in the X-direction. The two output terminals 92 are placed at substantially the same location in the Z-direction.

The signal terminals 93 are electrically connected to the circuit substrate 13 including the drive circuit. The signal terminals 93H are electrically connected to the pads 40P of the semiconductor elements 40H via connection members such as bonding wires 110. The signal terminals 93H include terminals for applying a drive voltage to the gate electrodes of the semiconductor elements 40H. The semiconductor device 20 in the present embodiment includes the two signal terminals 93H. The signal terminals 93H are placed at locations overlapping the notch 540 of the P-wiring 54 in the plan view. Of the signal terminals 93H, junction portions with the bonding wires 110 face not the top surface metal body 52, but the insulating base material 51. The two signal terminals 93H are arranged laterally in the X-direction.

The signal terminals 93H extend in the Y-direction from the junction portions with the bonding wires 110 to protrude from the vicinity of the middle of the side surface 30c in the Z-direction to the outside of the sealing body 30. At least a part of each of protruding portions of the signal terminals 93H extends in the same direction as directions in which the power source terminals 91 extend. The signal terminals 93H are arranged between the two P-terminals 91P in the X-direction. In other words, the external connection terminals 90 protruding from the side surface 30c are arranged in order of the N-terminal 91N, the P-terminal 91P, the two signal terminals 93H, the P-term inal 91P, and the N-terminal 91N in the X-direction. The two signal terminals 93H are arranged in a space between the power source terminals 91.

The signal terminals 93L are electrically connected to the pads 40P of the semiconductor elements 40L via connection members such as the bonding wires 110. The signal terminals 93L include terminals for applying the drive voltage to the gate electrodes of the semiconductor elements 40L. The semiconductor device 20 in the present embodiment includes the four signal terminals 93L. The signal terminals 93L are placed at locations overlapping the notch 550 of the relay wiring 55 in the plan view. Of the signal terminals 93L, junction portions with the bonding wires 110 face not the top surface metal body 52, but the insulating base material 51. The four signal terminals 93L are arranged laterally in the X-direction.

The signal terminals 93L extend in the Y-direction from the junction portions with the bonding wires 110 to protrude from the vicinity of the middle of the side surface 30d in the Z-direction to the outside of the sealing body 30. At least a part of each of protruding portions of the signal terminals 93L extends in the same direction as directions in which the output terminals 92 extend. The signal terminals 93L are arranged between the two output terminals 92 in the X-direction. In other words, the external connection terminals 90 protruding from the side surface 30d are arranged in the order of the output terminal 92, the four signal terminals 93L, and the output terminal 92 in the X-direction. The four signal terminals 93L are arranged in a space between the output terminals 92. Details of the signal terminals 93 (93H and 93L) and connection structures between the signal terminals 93 and the pads 40P will be described later.

The drain electrodes 40D of the semiconductor elements 40 are bonded to the top surface metal body 52 via joining materials 100. The source electrodes 40S of the semiconductor elements 40 are bonded to the conductive spacers 70 via joining materials 101. The conductive spacers 70 are bonded to the top surface metal body 62 via a joining material 102. The joint portion 81 is bonded to top the top surface metal bodies 52 and 62 via the joining materials 103. Of the external connection terminals 90, the P-terminals 91P, the N-terminals 91N, and the output terminals 92 each serving as a main terminal are bonded to the top surface metal bodies 52 and 62 via joining materials 104.

The joining materials 100 to 104 are joining materials each having a conductivity. For example, as the joining materials 100 to 104, a solder can be used. Examples of the solder include multi-element lead-free solders including not only Sn, but also Cu, Ni, and the like. Instead of the solder, a sintered joining material such as sintered silver may also be used.

The P-terminals 91P, the N-terminals 91N, and the output terminals 92 may also be bonded directly to the corresponding top surface metal bodies 52 and 62 without interposition of the joining materials 104. The P-terminals 91P, the N-terminals 91N, and the output terminals 92 may also be bonded directly to the top surface metal bodies 52 and 62 by, e.g., ultrasonic welding, friction stir welding, laser welding, or the like. When the joint portion 81 is provided separately from the substrates 50 and 60, the joint portion 81 may also be bonded directly to the top surface metal bodies 52 and 62.

As described above, in the semiconductor device 20, by the sealing body 30, the plurality of semiconductor elements 40 included in the upper/lower arm circuit 9 corresponding to one phase are sealed. The sealing body 30 integrally seals (covers) the plurality of semiconductor elements 40, a portion of the substrate 50, a portion of the substrate 60, the plurality of conductive spacers 70, the arm connection portion 80, and a portion of each of the external connection terminals 90. The sealing body 30 seals the insulating base materials 51 and 61 and the top surface metal bodes 52 and 62 over the substrates 50 and 60.

The semiconductor elements 40 are placed between the substrates 50 and 60 in the Z-direction. The semiconductor elements 40 are interposed between the substrates 50 and 60 placed to face each other. This allows heat in the semiconductor elements 40 to be dissipated on both sides in the Z-direction. The semiconductor device 20 has a double-sided heat dissipation structure. The back surface 50b of the substrate 50 is substantially flush with the one surface 30a of the sealing body 30. The back surface 60b of the substrate 60 is substantially flush with the back surface 30b of the sealing body 30. Since the back surfaces 50b and 60b are exposed surfaces, it is possible to increase a heat dissipation property.

The two semiconductor elements 40H (41H and 42H) arranged side by side in the X-direction are connected in parallel to each other by the top surface metal bodies 52 and 62, the conductive spacers 70, and the joining materials 100 to 102. The two semiconductor elements 40L (41L and 42L) arranged side by side in the X-direction are connected in parallel to each other by the top surface metal bodies 52 and 62, the conductive spacers 70, and the joining materials 100 to 102.

### Semiconductor Elements and Positions Thereof

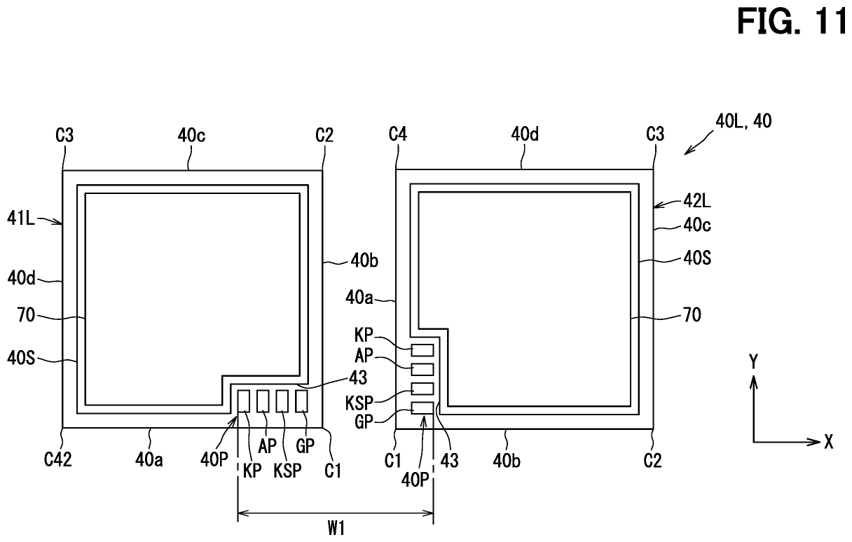

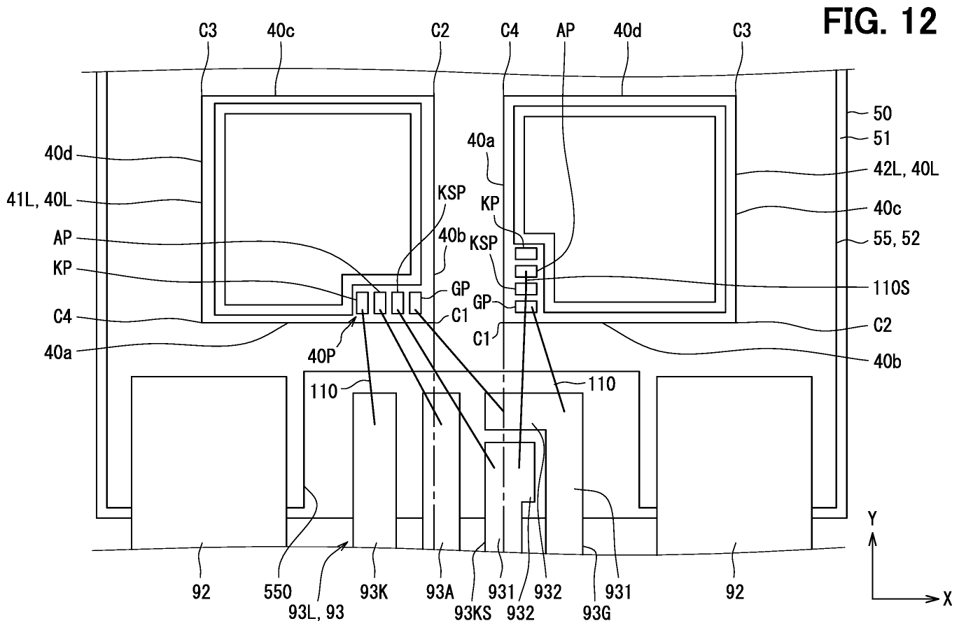

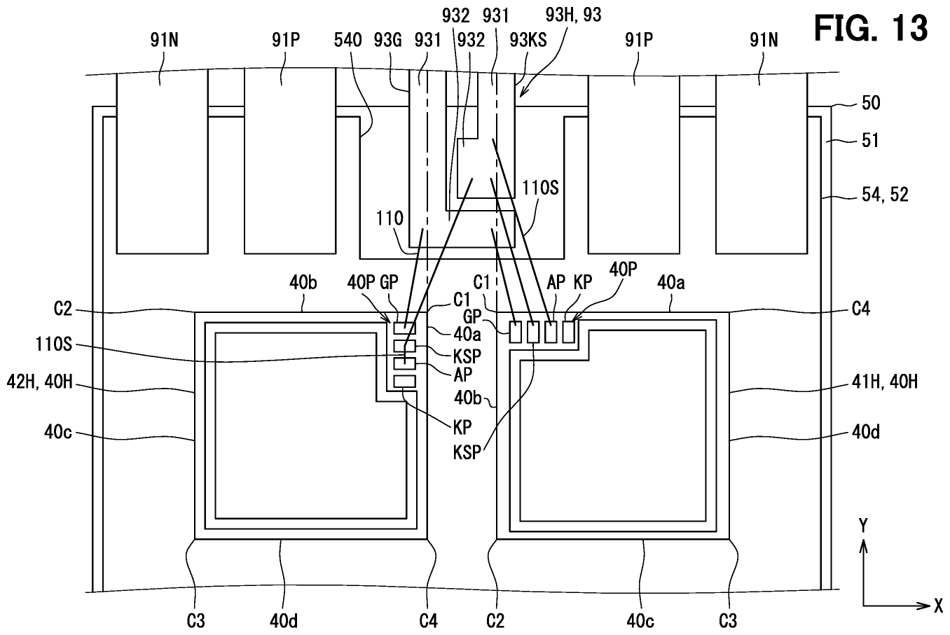

Next, on the basis of FIGS. 11 to 13, a description will be given of the semiconductor elements 40 and positions thereof. FIG. 11 is a plan view illustrating the positions of the plurality of semiconductor elements 40 arranged side by side in the X-direction. In FIG. 11, by way of example, the positions of the semiconductor elements 40L on the lower arm 9L side are shown. FIG. 12 illustrates respective positions of the signal terminals 93L and the semiconductor elements 40L (41L and 42L) on the lower arm 9L side and a wire connection structure. FIG. 13 illustrates respective positions of the signal terminals 93H and the semiconductor elements 40H (41H and 42H) on the upper arm side 9H.

In the following, the X-direction may be referred to also as a left-right direction. Specifically, a direction of the semiconductor element 42L viewed from the semiconductor element 41L may be referred to also as a right direction, while a direction of the semiconductor element 41L viewed from the semiconductor element 42L may be referred to also as a left direction. Meanwhile, the Y-direction may be referred to also as an upward/downward direction. Specifically, a direction of the semiconductor element 40L viewed from the semiconductor element 40H may be referred to also as a downward direction, while a direction of the semiconductor element 40H viewed from the semiconductor element 40L may be referred to also as an upward direction.

As illustrated in FIG. 11, each of the semiconductor elements 40 having a substantially rectangular planar shape has four corner portions C1, C2, C3, and C4 and four side portions 40a, 40b, 40c, and 40d. The corner portions C1 to C4 and the side portions 40a to 40d define an outline of the semiconductor element 40 in the plan view. The corner portions C1 and C3 are at positions diagonal to each other, while the corner portions C2 and C4 are at locations diagonal to each other. The side portion 40a is a side connecting the corner portions C1 and C4. The side portion 40b is a side connecting the corner portions C1 and C2. The side portion 40c is a side connecting the corner portions C2 and C3. The side portion 40c is a side opposite to the side portion 40a. The side portion 40d is a side connecting the corner portions C3 and C4. The side portion 40d is a side opposite to the side portion 40b.

The source electrode 40S has a notch 43. The source electrode 40S is notched so as to allow the pads 40P to be provided offset to the periphery (vicinity) of the corner portion C1. The notch 43 in the present embodiment has a substantially rectangular planar shape. The notch 43 is provided correspondingly to the corner portion C1. For example, in the semiconductor element 41L, the notch 43 has the X-direction as a longitudinal direction, while having the Y-direction as a lateral direction. In the semiconductor element 42L, the notch 43 has the X-direction as the lateral direction, while having the Y-direction as the longitudinal direction. The source electrode 40S has a shape obtained by removing the notch 43 from a substantially rectangular planar shape, i.e., a substantially L-shaped shape. Each of the conductive spacers 70 has the same shape as that of the source electrode 40S in the plan view.

Each of the semiconductor elements 40 has the four pads 40P. The pads 40P include a gate pad GP, a Kelvin source pad KSP, an anode pad AP, and a cathode pad KP. The gate pad GP is the pad 40P for applying the drive voltage to the gate electrode of each of the MOSFETs 11. In other words, the gate pad GP is the pad 40P for the gate electrode that controls the main current flowing between the drain electrode 40D and the source electrode 40S each serving as the main electrode. The Kelvin source pad KSP is the pad 40P for detecting a source potential of the MOSFET 11, i.e., a potential of the source electrode 40S. The anode pad AP is the pad 40P for detecting an anode potential of a temperature sensing diode included in the semiconductor element 40 and not shown. The cathode pad KP is the pad 40P for detecting a cathode potential of the temperature sensing diode. The kelvin source pad KSP corresponds to the Kelvin pad for detecting a potential of the second main electrode.

The pads 40P are provided in a pad formation region including a region formed with the notch 43 in the plan view. The pad formation region substantially matches, e.g., the region formed with the notch 43. The pad formation region is provided offset to the corner portion C1. In other words, the pads 40P are provided offset to the periphery (vicinity) of the corner portion C1. The pad formation region has a substantially rectangular planar shape. The plurality of pads 40P are arranged along the side portion 40a from a corner portion C1 side in order of the gate pad GP, the Kelvin source pad KSP, the anode pad AP, and the cathode pad KP. The corner portion C1 corresponds to a first corner portion.

As illustrated in FIGS. 11 and 12, of the two semiconductor elements 40L arranged side by side in the X-direction, the semiconductor element 41L serving as the first element is placed such that the side portion 40a faces the signal terminals 93L and the side portion 40b faces the semiconductor element 42L. The four pads 40P are arranged in the X-direction. The pads 40P are arranged side by side with the source electrode 40S in the Y-direction. The pads 40P are arranged offset to a signal terminal 93L side in the Y-direction. In the Y-direction, the pads 40P are arranged offset to a side portion 40a side. The pads 40P are arranged side by side with the source electrode 40S in the X-direction. In the X-direction, the pads 40P are arranged offset to a side portion 40b side.

The semiconductor element 42L serving as the second element is placed in a position resulting from 90-degree rotation from a position of the semiconductor element 41L around the axis along the Z-direction such that the pads 40P are closer to the semiconductor element 41L. The semiconductor element 42L is placed such that the side portion 40b faces the signal terminals 93L and the side portion 40a faces the semiconductor element 41L. The four pads 40P are arranged in the Y-direction. The pads 40P are arranged side by side with the source electrode 40S in the Y-direction. The pads 40P are arranged offset to a signal terminal 93L side in the Y-direction. In the Y-direction, the pads 40P are arranged on the side portion 40b side. The pads 40P are arranged side by side with the source electrode 40S in the X-direction. The pads 40P are arranged offset to a semiconductor element 41L side in the X-direction. In the X-direction, the pads 40P are arranged offset to the side portion 40a side. In each of the semiconductor elements 41L and 42L, the side portion 40a corresponds to a first side portion, while the side portion 40b corresponds to a second side portion.

Due to the position resulting from the 90-degree rotation, the corner portion C1 is located at a lower right position in the semiconductor element 41L, while being located at a lower left position in the semiconductor element 42L. In other words, the corner portion C1 of the semiconductor element 41L and the corner portion C1 of the semiconductor element 42L face each other in the X-direction. Accordingly, as illustrated in FIG. 11, in the X-direction, a width W1 of the region where the pads 40P are arranged in the two semiconductor elements 40L is short. The width W1 is a distance (length) between a portion of the pad 40P of the semiconductor element 41L most distant from the semiconductor element 42L and a portion of the pad 40P of the semiconductor element 42L most distant from the semiconductor element 41L in the X-direction. The pads 40P of the two semiconductor elements 40L are arranged offset to the signal terminal 93L side, i.e., on the side surface 30d side of the sealing body 30 in the Y-direction.

As described above, the positions of the semiconductor elements 41H and 42H and the positions of the semiconductor elements 41L and 42L have two-fold symmetry around the axis along the Z-direction. The two semiconductor elements 40H substantially match positions resulting from 180-degree rotation of the two semiconductor elements 40L around the axis along the Z-direction, i.e., inversion thereof. Accordingly, in the semiconductor elements 40H and the semiconductor elements 40L, the positions of the first elements and the second elements are opposite in the X-direction (left-right direction).

As illustrated in FIG. 13, of the two semiconductor elements 40H arranged side by side in the X-direction, the semiconductor element 41H serving as the first element is placed such that the side portion 40a faces the signal terminals 93H and the side portion 40b faces the semiconductor element 42H. The four pads 40P are arranged in the X-direction. The pads 40P are arranged side by side with the source electrode 40S in the Y-direction. In the Y-direction, the pads 40P are arranged offset to a signal terminal 93H side. In the Y-direction, the pads 40P are arranged offset to the side portion 40a side. The pads 40P are arranged side by side with the source electrode 40S in the X-direction. The pads 40P are arranged offset to a semiconductor element 42H side in the X-direction. In the X-direction, the pads 40P are arranged offset to a side portion 40b side.

The semiconductor element 42H serving as the second element is placed in a position resulting from 90-degree rotation from a position of the semiconductor element 41H around the axis along the Z-direction such that the pads 40P are closer to the semiconductor element 41H. The semiconductor element 42H is placed such that the side portion 40b faces the signal terminals 93H and the side portion 40a faces the semiconductor element 41H. The four pads 40P are arranged in the Y-direction. The pads 40P are arranged side by side with the source electrode 40S in the Y-direction. The pads 40P are arranged offset to the signal terminal 93H side in the Y-direction. In the Y-direction, the pads 40P are offset to the side portion 40b side. The pads 40P are side by side with the source electrode 40S in the X-direction. The pads 40P are arranged offset to the semiconductor element 41L side in the X-direction. In the X-direction, the pads 40P are arranged offset to the side portion 40a side. In each of the semiconductor elements 41H and 42H, the side portion 40a corresponds to the first side portion, while the side portion 40b corresponds to the second side portion.

Due to the placement at the position resulting from the 90-degree rotation, the angle C1 is located at an upper left position in the semiconductor element 41H, while being located at an upper right position in the semiconductor element 42H. In other words, the corner portion C1 of the semiconductor element 41H and the corner portion C1 of the semiconductor element 42H face each other in the X-direction. Accordingly, in the X-direction, a width of the region where the pads 40P are arranged in the two semiconductor elements 40H is short. The width of the region where the pads 40P are arranged in the semiconductor elements 40H is equal to, e.g., the width W1 described above. The pads 40P of the two semiconductor elements 40H are arranged offset to the signal terminal 93H side, i.e., to the side surface 30c side of the sealing body 30 in the Y-direction.

The pads 40P of the semiconductor elements 40H and the pads 40P of the semiconductor elements 40L are offset not to sides (side portions 40c and 40d) facing each other in the Y-direction corresponding to the direction in which the semiconductor elements 40H and 40L are arranged, but to sides (side portions 40a and 40b) opposite to the facing sides.

### Arrangement of Signal Terminals and Connection Structures between Signal Terminals and Pads

Next, on the basis of FIGS. 12 and 13, a description will be given of an arrangement of the signal terminals 93 and connection structures between the signal terminals 93 and the pads 40P.

As described above, the semiconductor device 20 has, as the signal terminals 93, the two signal terminals 93H and the four signal terminals 93L. In the Y-direction, the signal terminals 93H are arranged such that the semiconductor elements 40 are interposed between the signal terminals 93H and the signal terminals 93L. The signal terminals 93H are arranged side by side together with the four power source terminals 91 (91P and 91N) in the X-direction. The signal terminals 93H are arranged between the power source terminals 91. The signal terminals 93L are arranged side by side together with the two output terminals 92 in the X-direction. The signal terminals 93L are arranged between the output terminals 92. To suppress an increase of a physical size in the X-direction, the two signal terminals 93H and the four signal terminals 93L are provided. Thus, the number of the external connection terminals 90 on each of the side surface 30c side and the side surface 30d is set to 6.

As illustrated in FIG. 12, the signal terminals 93L include a gate terminal 93G, a Kelvin source terminal 93KS, an anode terminal 93A, and a cathode terminal 93K. The four signal terminals 93L are arranged in a direction from the semiconductor element 42L toward the semiconductor element 41L in order of the gate terminal 93G, the Kelvin source terminal 93KS, the anode terminal 93A, and the cathode terminal 93K. An arrangement of the four signal terminals 93L corresponds to an arrangement of the pads 40P of the semiconductor element 41L serving as the first element. The signal terminals 93L correspond to juxtaposed terminals for the semiconductor elements 40L.

Of the four signal terminals 93L, the gate electrode 93G and the Kelvin source terminal 93KS have first extending portions 931 and second extending portions 932. The first extending portions 931 extend in the Y-direction in the plan view. To allow the plurality of bonding wires 110 to be connected thereto, the second extending portions 932 extend from the first extending portions 931 in the X-direction. Since the bonding wires 110 can be connected to the second extending portions 932 extending in the X-direction, angles of the bonding wires 110 with respect to a reference line substantially parallel to the Y-direction can be set gentle. The second extending portions 932 in the present embodiment are continued to respective end portions of the first extending portions 931 on a semiconductor element 40L side. As a result, each of the gate terminal 93G and the Kelvin source terminal 93KS has a substantially letter-L planar shape.

The gate terminal 93G and the Kelvin source terminal 93KS are placed such that the respective second extending portions 932 thereof are arranged in the Y-direction, i.e., face each other in the Y-direction. In the Y-direction, the second extending portion 932 of the gate electrode 93G is closer to the semiconductor elements 40L than the second extending portion 932 of the Kelvin source terminal 93KS. Each of the anode terminal 93A and the cathode terminal 93K extends in the Y-direction in the plan view. Neither the anode terminal 93A nor the cathode terminal 93K has the second extending portion 932.

The signal terminals 93L have portions located between the side portion 40b of the semiconductor element 41L and the side portion 40a of the semiconductor element 42L which are arranged side by side in the X-direction. Specifically, a portion of the gate electrode 93G, a portion of the Kelvin source terminal 93KS, and a portion of the anode terminal 93A are located between the semiconductor elements 41L and 42L in the X-direction, i.e., in a non-element arrangement region between dash-dot lines illustrated in FIG. 12.

In the semiconductor element 41L, the gate pad GP is connected to the gate terminal 93G via the bonding wire 110. The Kelvin source pad KSP is connected to the Kelvin source terminal 93KS via the bonding wire 110. The anode pad AP is connected to the anode terminal 93A via the bonding wire 110. The cathode pad KP is connected to the cathode terminal 93K via the bonding wire 110. All the bonding wires 110 connected to the semiconductor element 41L cross the side portion 40a in the plan view.

In the semiconductor element 42L, the gate pad GP is connected to the gate terminal 93G via the bonding wire 110. The Kelvin source pad KSP is connected to the Kelvin source terminal 93KS via the bonding wire 110. The anode pad AP is connected to the Kelvin source pad KSP located adjacent thereto via a bonding wire 110S. To the cathode pad KP, the bonding wire 110 is not connected. The anode of the temperature sensing diode is connected to the Kelvin source pad KSP to be fixed to a source potential. All the bounding wires 110 connected to the semiconductor element 42L cross the side portion 40b in the plan view.

The bonding wire 110S may also be continued to the bonding wire 110 connecting the Kelvin source pad KSP and the Kelvin source terminal 93KS. In other words, the bonding wire 110S may also be a portion of the bonding wire 110 connecting the Kelvin source pad KSP and the Kelvin source terminal 93KS. The bonding wire 110S may also be provided separately from the bonding wire 110 connecting the Kelvin source pad KSP and the Kelvin source terminal 93KS.

In each of the semiconductor elements 41L and 42L, the gate pad GP is connected to the second extending portion 932 of the corresponding gate terminal 93G via the bonding wire 110. In each of the semiconductor elements 41L and 42L, the Kelvin source pad KSP is connected to the second extending portion 932 of the corresponding Kelvin source terminal 93KS via the bonding wire 110. Only in the semiconductor element 41L, the anode pad AP is connected to the corresponding anode terminal 93A via the bonding wire 110. Only in the semiconductor element 41L, the cathode pad KP is connected to the corresponding cathode terminal 93K via the bonding wire 110.

As illustrated in FIG. 13, the signal terminals 93H include the gate terminal 93G and the Kelvin source terminal 93KS. The two signal terminals 93H are arranged in order of the gate terminal 93G and the Kelvin source terminal 93KS in a direction from the semiconductor element 41H toward the semiconductor element 42H. The signal terminals 93H include neither the anode terminal 93A nor the cathode terminal 93K. The signal terminals 93H correspond to the juxtaposed terminals for the semiconductor elements 40H.

The gate terminal 93G and the Kelvin source terminal 93KS of the signal terminals 93H also have the first extending portions 931 and the second extending portions 932. Each of the gate terminal 93G and the Kelvin source terminal 93KS has a substantially L-shaped planar shape. The gate terminal 93G and the Kelvin source terminal 93KS are placed such that the respective second extending portions 932 thereof are arranged in the Y-direction, i.e., face each other in the Y-direction. In the Y-direction, the second extending portion 932 of the gate electrode 93G is closer to the semiconductor elements 40H than the second extending portion 932 of the Kelvin source terminal 93KS.

The signal terminals 93H have portions located between the side portion 40b of the semiconductor element 41H and the side portion 40a of the semiconductor element 42H which are arranged side by side in the X-direction. Specifically, a portion of the gate terminal 93G and a portion of the Kelvin source terminal 93KS are located between the semiconductor elements 41H and 42H in the X-direction, i.e., in a non-element arrangement region between dash-dot lines illustrated in FIG. 13.

In the semiconductor element 41H, the gate pad GP is connected to the gate terminal 93G via the bonding wire 110. The Kelvin source pad KSP is connected to the Kelvin source terminal 93KS via the bonding wire 110. The anode pad AP is connected to the Kelvin source terminal 93KS via the bonding wire 110S. To the cathode pad KP, the bonding wire 110 is not connected. The anode of the temperature sensing diode is connected to the Kelvin source terminal 93KS to be fixed to the source potential. All the bonding wires 110 connected to the semiconductor element 41H cross the side portion 40a in the plan view.

In the semiconductor element 42H, the gate pad GP is connected to the gate terminal 93G via the bonding wire 110. The Kelvin source pad KSP is connected to the Kelvin source terminal 93KS via the bonding wire 110. The anode pad AP is connected to the Kelvin source pad KSP via the bonding wire 110S. To the cathode pad KP, the bonding wire 110 is not connected. The anode oof the temperature sensing diode is connected to the Kelvin source pad KSP to be fixed to the source potential. All the bonding wires 110 connected to the semiconductor element 42H cross the side portion 40b in the plan view.

In each of the semiconductor elements 41H and 42H, the gate pad GP is connected to the second extending portion 932 of the corresponding gate terminal 93G via the bonding wire 110. In each of the semiconductor elements 41H and 42H, the Kelvin source pad KSP is connected to the second extending portion 932 of the corresponding Kelvin source terminal 93KS via the bonding wire 110.

### Connection Structure between Signal Terminals and Circuit Substrate

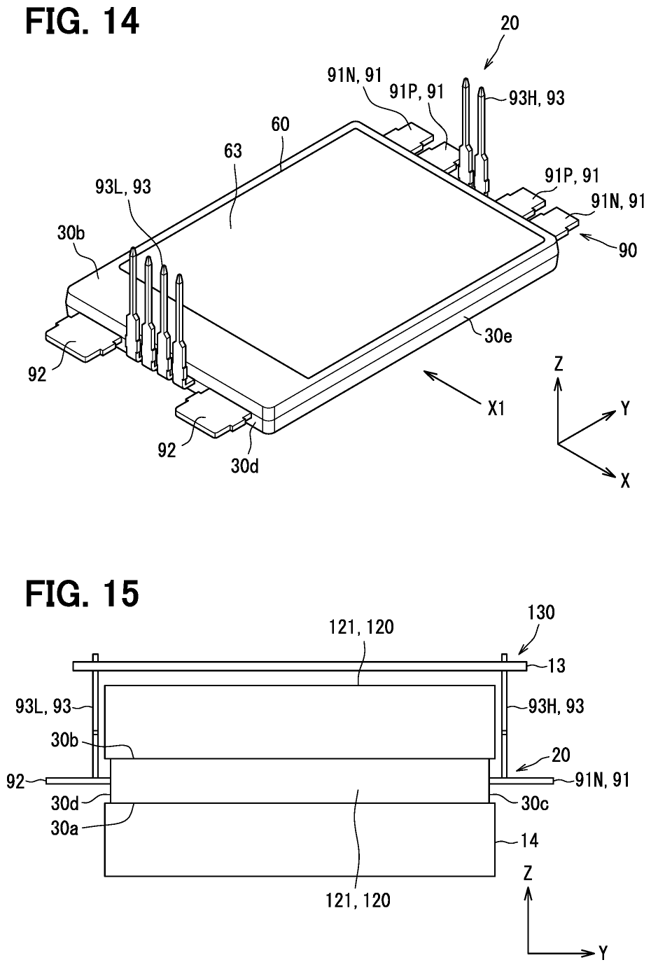

Next, on the basis of FIGS. 14 and 15, a description will be given of a connection structure between the signal terminals 93 and the circuit substrate 13 in the semiconductor device 20. FIG. 14 illustrates bent states of the signal terminals 93. FIG. 15 illustrates the connection structure between the signal terminals 93 and the circuit substrate 13. FIG. 15 is a side view obtained by viewing FIG. 14 from an X-direction.

The signal terminals 93 in the present embodiment are bent so as to be connected to the circuit substrate 13. The signal terminals 93 are bent by, e.g., press working or the like. As illustrated in FIGS. 14 and 15, the signal terminals 93 are bent outside the sealing body 30 to extend in the Z-direction. The signal terminal 93 are bent at an angle of substantially 90 degrees. All the signal terminals 93 extend on a back surface 30b side of the sealing body 30 that has the one surface 30a and the back surface 30b. Each of the signal terminals 93 has a portion extending in the Y-direction and a portion extending in the Z-direction.

All the signal terminals 93 (93H and 93L) are connected to the common (single) circuit substrate 13. In the example illustrated in FIG. 15, the signal terminals 93 are inserted through non-illustrated through holes of the circuit substrate 13 to be mounted. The circuit substrate 13 is placed at a predetermined distance from the semiconductor device 20 (sealing body 30).

In the example illustrated in FIG. 15, on both sides of the semiconductor device 20 in the Z-direction, heat exchanging units 121 of coolers 120 are placed. The heat exchanging units121 have the semiconductor device 20 interposed therebetween in the Z-direction. The coolers 120 cool the semiconductor device 20 with a refrigerant flowing in flow paths of the heat exchanging units 121. Examples of the refrigerant that can be used as the refrigerant allowed to flow in the flow paths include a refrigerant with a phase change such as water or ammonia and a refrigerant without a phase change such as an ethylene glycol type. The heat exchanging unit 121 on the back surface 30b of the sealing body 30 is placed in a gap between the circuit substrate 13 and the semiconductor device 20. The semiconductor device 20 is included, together with the circuit substrate 13 and the coolers 120, in a power module 130. The power module 130 may also include the semiconductor devices 20 corresponding to three phases which are arranged side by side in the X-direction. The circuit substrate 13 may also be provided commonly to the signal terminals 93 of the semiconductor devices 20 corresponding to the three phases.

### Summation of First Embodiment

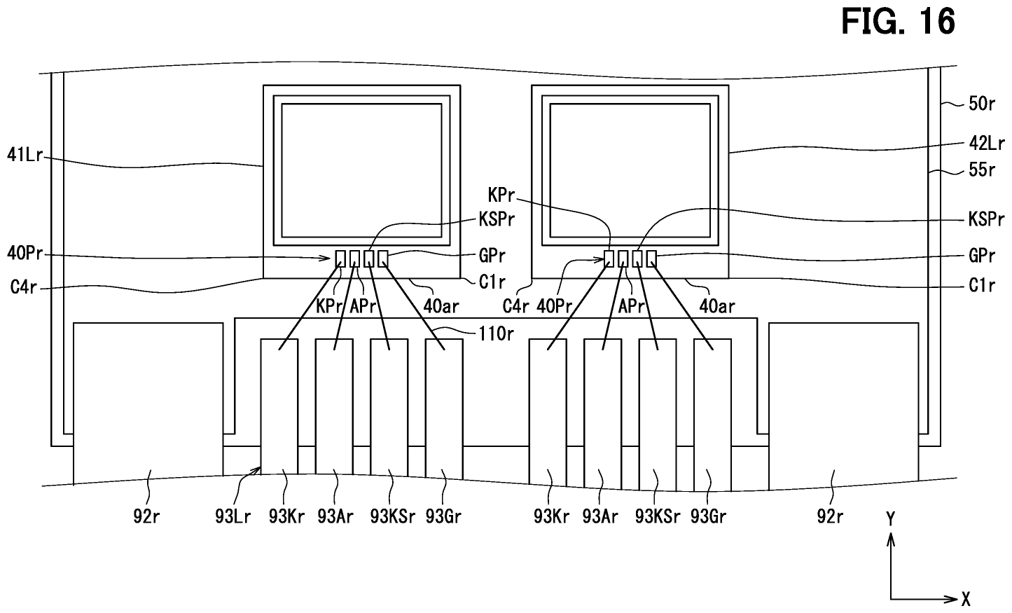

FIG. 16 is a plan view illustrating a reference example. FIG. 16 corresponds to FIG. 12. In the figure illustrating the reference example, each of reference signs of individual components has r added to an end of each of the reference signs related to the semiconductor devices 20.

FIG. 16 illustrates, by way of example, connection structures between semiconductor elements 41Lr and 42Lr and signal terminals 93L. In each of the semiconductor elements 41Lr and 42Lr, four pads 40Pr are arranged along a side portion 40ar in the X-direction. In the same manner as in the present embodiment, the pads 40Pr are arranged in order of a gate pad GPr, a Kelvin source pad KSPr, an anode pad APr, and a cathode pad KPr from a corner portion C1r side. The pads 40Pr are not offset to a corner portion C1r in the X-direction, and are provided in the vicinity of a middle of the side portion 40ar, i.e., at middle positions between the corner portion C1r and a corner portion C4r. The semiconductor element 42Lr has not rotated 90 degrees with respect to the semiconductor element 41Lr, and is placed in the same position as that of the semiconductor element 41Lr in the plan view. The locations of the semiconductor elements 41Lr and 42Lr in the plan view are the same as the locations of the semiconductor elements 41L and 42L.

Signal terminals 93Lr are provided for the individual pads 40Pr. To the semiconductor element 41Lr, the four signal terminals 93Lr, specifically a gate terminal 93Gr, a Kelvin source terminal 93KSr, an anode terminal 93Ar, and a cathode terminal 93Kr are connected. To the semiconductor element 42Lr, in the same manner as to the semiconductor element 41Lr, the four signal terminals 93Lr are connected. The signal terminals 93Lr are connected to the corresponding pads 40Pr via bonding wires 110r.

As described above, in the reference example, for each of the semiconductor elements 41Lr and 42Lr, the same number of the signal terminals 93Lr as that of the pads 40Pr are provided such that lengths of the bonding wires 110r are reduced as much as possible and that angles of the bonding wires 110r are as gentle as possible. Note that the angles of the bonding wires 110r are angles formed between portions of the bonding wires 110r connecting the pads 40Pr and the signal terminals 93Lr and a reference line substantially parallel to the Y-direction corresponding to directions in which the pads 40P extend.

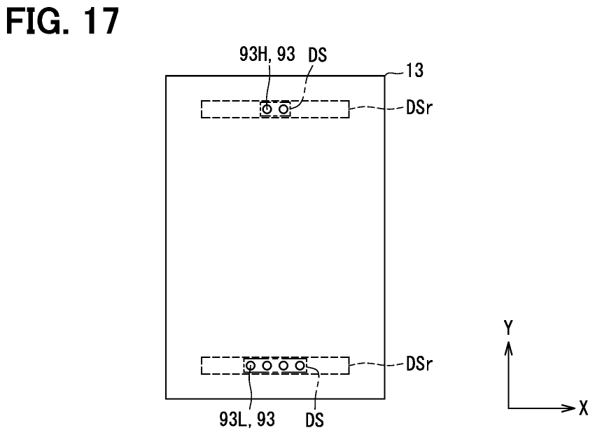

FIG. 17 illustrates dead spaces of the circuit substrate 13 resulting from the signal terminals. In FIG. 17, dead spaces DS due to the semiconductor devices 20 in the present embodiment are indicated by dash-dot lines. As reference lines, dead spaces DSr according to the reference example illustrated in FIG. 16 are indicated by broken lines.

The dead spaces are portions of the circuit substrate 13 connected to the signal terminals corresponding to the first element, portions thereof connected to the signal terminals corresponding to the second element, and regions thereof between the connected portions. The dead spaces may be referred to also as mounting inhibited regions. As illustrated in FIG. 16, in the case of the reference example, distances between the pads 40Pr in the semiconductor elements 41Lr and 42Lr are long, and regions where the pads 40Pr are arranged in the two semiconductor elements 41Lr and 42Lr are also large. Accordingly, regions between the portions connected to the signal terminals 93Lr corresponding to the semiconductor element 41Lr and the portions connected to the signal terminals 93Lr corresponding to the semiconductor element 42Lr are elongated. In addition, regions where the signal terminals 93Lr corresponding to the two semiconductor elements 41Lr and 42Lr are arranged are also elongated. As a result, as illustrated in Fig, 17, the dead spaces DSr are enlarged. In FIG. 17, the dead space DSr on an upper arm side is also illustrated.

By contrast, in the semiconductor device 20 in the present embodiment, the semiconductor elements 41L and 42L arranged side by side in the X-direction have the structures common to each other. In the common structures, the pads 40P are provided offset to the peripheries of the corner portions C1. The semiconductor element 41L is placed such that the side portion 40a faces the signal term inals 93L in the Y-direction and that the side portion 40b faces the semiconductor element 42L in the X-direction. The semiconductor element 42L is placed in the position resulting from the 90-degree rotation from the position of the semiconductor element 41L such that the side portion 40b faces the signal terminals 93L in the Y-direction and that the side portion 40a faces the semiconductor element 41L in the X-direction. Due to the positions of the semiconductor elements 41L and 42L described above, as illustrated in FIG. 11, pad arrangement regions of the two semiconductor elements 41L and 42L are shortened in the X-direction. Since the pad arrangement regions are shortened, the regions where the plurality of signal terminals 93L are arranged can be shortened in the X-direction.

Likewise, the semiconductor elements 41H and 42H arranged side by side in the X-direction have the structures common to each other. In the common structures, the pads 40P are provided offset to the peripheries of the corner portions C1. The semiconductor element 41H is placed such that the side portion 40a faces the signal terminals 93H in the Y-direction and that the side portion 40b faces the semiconductor element 42H in the X-direction. The semiconductor element 42H is placed in the position resulting from the 90-degree rotation from the position of the semiconductor element 41H such that the side portion 40b faces the signal terminals 93H in the Y-direction and that the side portion 40a faces the semiconductor element 41H in the X-direction. Due to the positions of the semiconductor elements 41H and 42H described above, pad arrangement regions of the two semiconductor elements 41H and 42H are shortened in the X-direction. Since the pad arrangement regions are shortened, the regions where the plurality of signal terminals 93H are arranged can be shortened in the X-direction.

Thus, with the semiconductor device 20 in the present embodiment, the pad arrangement regions and the regions of the circuit substrate 13 where the signal terminals 93 are arranged can be set smaller than those in the reference example. Therefore, in the circuit substrate 13, the dead spaces DS resulting from the signal terminals 93 can be reduced.

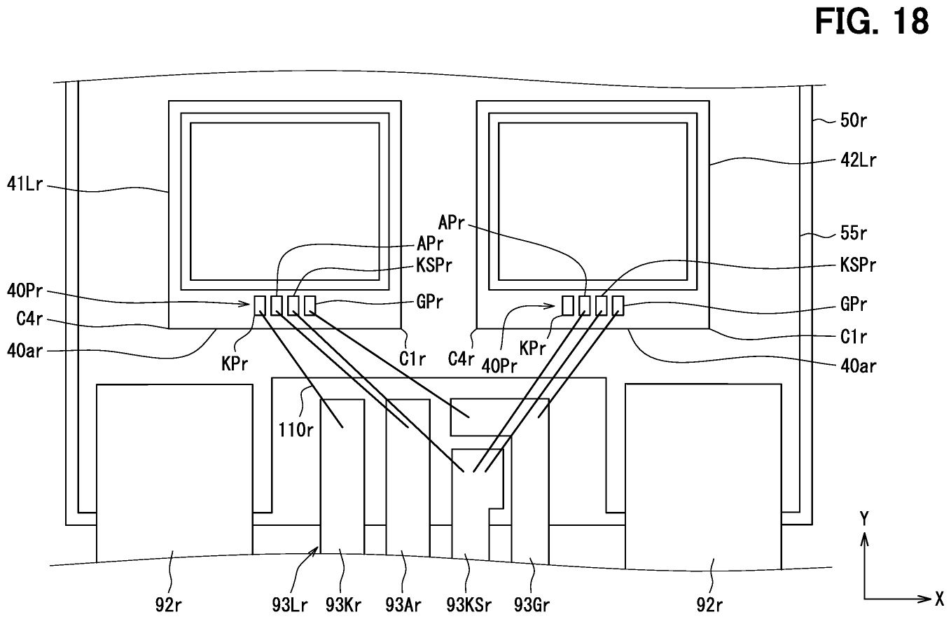

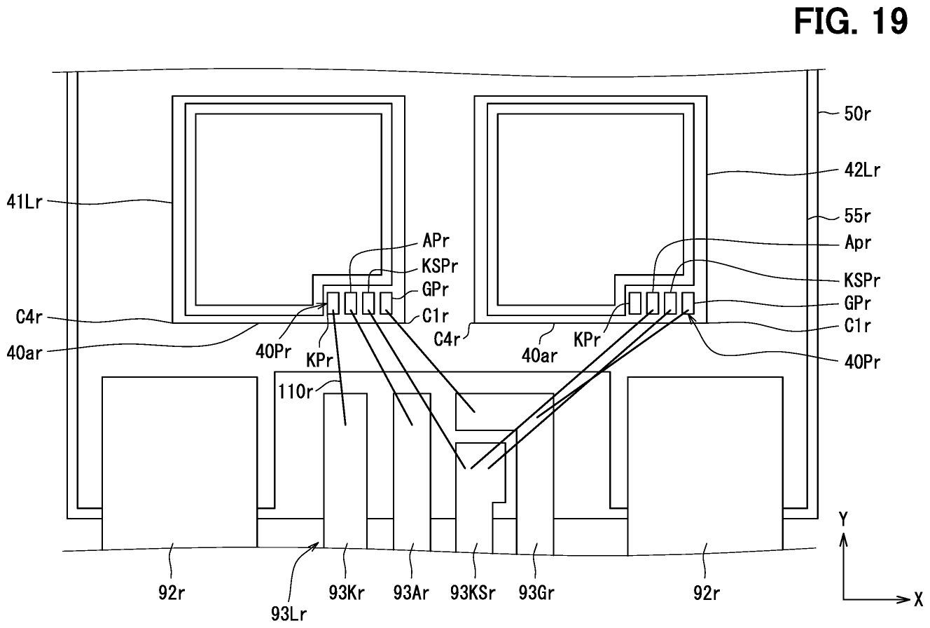

FIGS. 18 and 19 illustrate connection structures between the signal terminals and the pads in reference examples other than that in FIG. 16. FIGS. 18 and 19 also correspond to FIG. 12. In the reference example illustrated in FIG. 18, the placement of the pads 40Pr and the locations of the semiconductor elements 41Lr and 42Lr are the same as those in the configuration illustrated in FIG. 16. Other configurations are the same as those in the semiconductor device 20. In the reference example illustrated in FIG. 18, similarly to the signal terminals 93L in the present embodiment, the signal terminals 93Lr include each one of the gate terminal 93Gr, the Kelvin source terminal 93KSr, the anode terminal 90Ar, and the cathode terminal 93Kr.

As illustrated in FIG. 18, the gate pads GPr of the semiconductor elements 41Lr and 42Lr are connected to the common gate terminal 93Gr via the bonding wires 110r. The Kelvin source pads KSPr of the semiconductor elements 41Lr and 42Lr are connected to the common Kelvin source terminal 93KSr via the bonding wires 110r. The anode pad APr of the semiconductor element 41Lr is connected to the anode terminal 93Ar via the bonding wire 110r, while the anode pad APr of the semiconductor element 42Lr is connected to the Kelvin source terminal 93KSr via the bonding wire 110r. The cathode pad KPr of the semiconductor element 41Lr is connected to the cathode terminal 93Kr via the bonding wire 110r, while the cathode pad KPr of the semiconductor element 42Lr is not connected to the signal terminal 93Lr.

From a comparison with FIG. 12, it is obvious that at least some of the plurality of bonding wires 110r illustrated in FIG. 18 have wire lengths longer than those of the bonding wires 110 in the present embodiment. In addition, at least some of the plurality of bonding wires 110r have angles steeper (larger) than those of the bonding wires 110 in the present embodiment.

In the reference example illustrated in FIG. 19, arrangements of the pads 40Pr in the semiconductor elements 41Lr and 42Lr are the same as those in the configuration illustrated in the present embodiment. The pads 40Pr are provided offset to the corner portions C1r. The four pads 40Pr are arranged along each of the side portions 40ar in the X-direction. The pads 40Pr are arranged in order of the gate pad GPr, the Kelvin source pad KSPr, the anode pad APr, and the cathode pad KPr from the corner portion C1r side. The semiconductor element 42Lr is not placed in a position resulting from 90-degree rotation from the semiconductor element 41Lr, and is placed in the same position as that of the semiconductor element 41Lr in the plan view. Other configurations are the same as those in the semiconductor device 20. In the reference example illustrated in FIG. 19 also, the signal terminals 93Lr include each one of the gate terminal 93Gr, the Kelvin source terminal 93KSr, the anode terminal 90Ar, and the cathode terminal 93Kr.

From a comparison with FIG. 12, it is obvious that at least some of the plurality of bonding wires 110r illustrated in FIG. 19 have wire lengths longer than those of the bonding wires 110 in the present embodiment. In addition, at least some of the plurality of bonding wires 110r have angles steeper (larger) than those of the bonding wires 110 in the present embodiment. Furthermore, some of the bonding wires 110r cross other bonding wires 110r in the plan view.

In each of the examples illustrated in FIGS. 18 and 19, the arrangement of the signal terminals 93Lr that simply reduces a region where the signal terminals 93Lr are arranged is adopted in order to reduce the dead spaces DSr, and therefore the regions where the pads 40Pr are arranged are sufficiently long compared to the region where the signal terminals 93Lr are arranged. Accordingly, at least some of the bonding wires 110r have increased lengths or increased angles. When the bonding wires 110r are elongated, variation in length of the plurality of bonding wires 110r connected to the common signal terminal 93Lr is increased. In particular, when variation in length of the bonding wires 110r connecting the gate pads GPr and the gate terminal 93Lr is large, a difference in drive voltage application timing occurs between the semiconductor elements 41Lr and 42Lr, and one of the semiconductor elements 41Lr and 42Lr may be turned ON before another thereof is turned ON. In other words, a current may be concentrated on one of the semiconductor elements 41Lr and 42Lr. In addition, when the bonding wires 110r are long, wire sweep may occur during molding of the sealing body 30, i.e., a short circuit or disconnection may occur. When the angles of the bonding wires 110r are large, in each of the bonding wires 110r, a neck portion (bent portion) to be withdrawn from a portion connected to the pad 40Pr to the signal terminal 93Lr is thinned, and a conduction failure, such as disconnection, may occur.

In the present embodiment, the two semiconductor elements 40 juxtaposed in the X-direction are provided to have the common structures in which the pads 40P are provided offset to the peripheries of the corner portions C1, and one of the semiconductor elements 40 (42H and 42L) is placed in the position resulting from the 90-degree rotation from the position of the other one of the semiconductor elements 40 (41H and 41L). Thus, the length (width W1) of the region where the pads 40P are arranged can be reduced compared to that in the reference example illustrated in FIGS. 18 and 19. Therefore, it is possible to suppress degradation of reliability related to the bonding wires 110, while reducing the dead spaces DS.

In particular, in the present embodiment, as illustrated in FIGS. 12 and 13, the gate pads GP are closer to the corner portions C1 than the other pads 40P. Among the plurality of pads 40P, the gate pads GP are closest to the corner portions C1. Consequently, in the two semiconductor elements 40 juxtaposed in the X-direction, the gate pads GP are close to each other and placed at substantially the same position in the Y-direction. Accordingly, it is possible to shorten the respective lengths of the bonding wires 110 connecting the two gate pads GP and the common gate terminal 93G. Since the lengths are short, variation in length is also reduced, and it is possible to suppress the occurrence of the difference in the drive voltage application timing. In other words, it is possible to inhibit the main current from flowing unevenly in one of the semiconductor elements 40.

In the present embodiment, the signal terminals 93L corresponding to the plurality of juxtaposed terminals have portions located between the side portion 40b of the semiconductor element 41L and the side portion 40a of the semiconductor element 42L in the X-direction. Likewise, the signal terminals 93H corresponding to the plurality of juxtaposed terminals have portions located between the side portion 40b of the semiconductor element 41H and the side portion 40a of the semiconductor element 42H in the X-direction. This can shorten the regions where the signal terminals 93 are arranged and further reduce the dead spaces DS in the circuit substrate 13. In addition, the angles of the bonding wires 110 connected to the signal terminals 93 located between the two semiconductor elements 40 can be set gentler (smaller). This can suppress the occurrence of a conduction failure, such as disconnection, in the bonding wires 110.

In a configuration in which the plurality of semiconductor elements 40 are arranged side by side and the juxtaposed semiconductor elements 40 are thermally connected to each other, it is also possible to use only the temperature sensing diode of one of the semiconductor elements 40 and ensure overheated states of the plurality of semiconductor elements 40. Accordingly, it may also be possible to connect only one of the plurality of semiconductor elements 40 to the anode terminal 93A and the cathode terminal 93K. In this case, it is possible to reduce the number of the signal terminals 93. However, when the temperature sensing diodes unconnected to each of the anode terminal 93A and the cathode terminal 93K are left in a so-called floating state to be potentially floating, a problem may occur in the semiconductor elements 40.

In the present embodiment, the anode pad AP is provided adjacent to the Kelvin source pad KSP. Of the two juxtaposed semiconductor elements 40L, the semiconductor element 42L has the anode pad AP electrically connected to the cathode pad KP located adjacent thereto. This can inhibit the temperature sensing diode from coming into the floating state, while reducing the number of the signal terminals 93L. Since the anode pad AP is located adjacent to the Kelvin source pad KSP, the connection structure can be simplified.

In particular, in the present embodiment, the semiconductor elements 40H and the semiconductor elements 40L are thermally connected via the substrates 50 and 60. Consequently, of the four semiconductor elements 40, only the semiconductor element 41L is connected to each of the anode terminal 93A and the cathode terminal 93K. Of the two juxtaposed semiconductor elements 40H, the semiconductor element 41H has the anode pad AP electrically connected to the cathode pad KP located adjacent thereto. Meanwhile, the semiconductor element 42H has the anode pad AP connected, together with the Kelvin source pad KSP located adjacent thereto, to the common Kelvin source terminal 93KS. In other words, the anode pad AP is electrically connected to the Kelvin source pad KSP via the Kelvin source terminal 93KS. This can inhibit the temperature sensing diode from coming into the floating state, while reducing the number of the signal terminals 93H. In particular, it is possible to reduce the number of the signal terminals 93H including a large number of the juxtaposed main terminals to a number smaller than that of the signal terminals 93L. This can suppress an increase in the physical size of the semiconductor device 20 in the X-direction.

The example in which the anode pad AP is located adjacent to the Kelvin source pad KSP has been described, but the pad located adjacent to the Kelvin source pad KSP is not limited thereto. It may also be possible to provide the cathode pad KP adjacent to the Kelvin source pad KSP. By electrically connecting the cathode pad KP to the Kelvin source pad KSP, it is possible to inhibit the temperature sensing diode from coming into the floating state, while reducing the number of the signal terminals 93.

The connection structure between the anode pad AP or the cathode pad KP and the Kelvin source pad KSP located adjacent thereto is not limited to the example described above. The anode pad AP or the cathode pad KP may also be connected to the Kelvin source pad KSP via the bonding wire 110S, or may also be connected to the Kelvin source terminal 93KS via the bonding wire 110S. In either case, the anode pad AP or the cathode pad KP is electrically connected to the Kelvin source pad SP. Since the Kelvin source pad KSP is located adjacent to the anode pad AP or the cathode pad KP, the connection structure can be simplified. For example, it is possible to reduce an electrical connection distance between the anode pad AP or the cathode pad KP and the Kelvin source pad KSP. In addition, it is possible to inhibit the bonding wires 110S from crossing the bonding wires 110 or occurrence of contact or the like therebetween.

The number of the semiconductor elements 40 arranged side by side in the X-direction and connected in parallel to each other is not limited to 2. The three or more semiconductor elements 40 may also be arranged in the X-direction and connected in parallel to each other. In this case also, the pads 40P are arranged offset to the corner portions C1. For example, in a configuration in which the three semiconductor elements 40 are arranged side by side, one of the two adjacent semiconductor elements 40 is placed in a position resulting from 90-degree rotation from a position of another thereof such that the individual corner portions C1 face each other. The remaining one semiconductor element 40 is placed in the same position as that of the adjacent semiconductor element 40. For example, in the configuration illustrated in FIG. 12, when the one semiconductor element 40L is added and placed adjacent to the semiconductor element 42L, the additional semiconductor element 40L is preferably placed in the same position as that of the semiconductor element 42L and, when the one semiconductor element 40L is placed adjacent to the semiconductor element 41L, the semiconductor element 40L is preferably placed in the same position as that of the semiconductor element 41L.

### Second Embodiment

This embodiment is one of modifications of the preceding embodiment as a basic configuration and may incorporate description of the preceding embodiment. In the preceding embodiment, the plurality of pads 40P are provided to be arranged in a row along the side portion 40a. Instead of this, the pads 40P may also be provided to be arranged along an inclined surface of the notch 43.

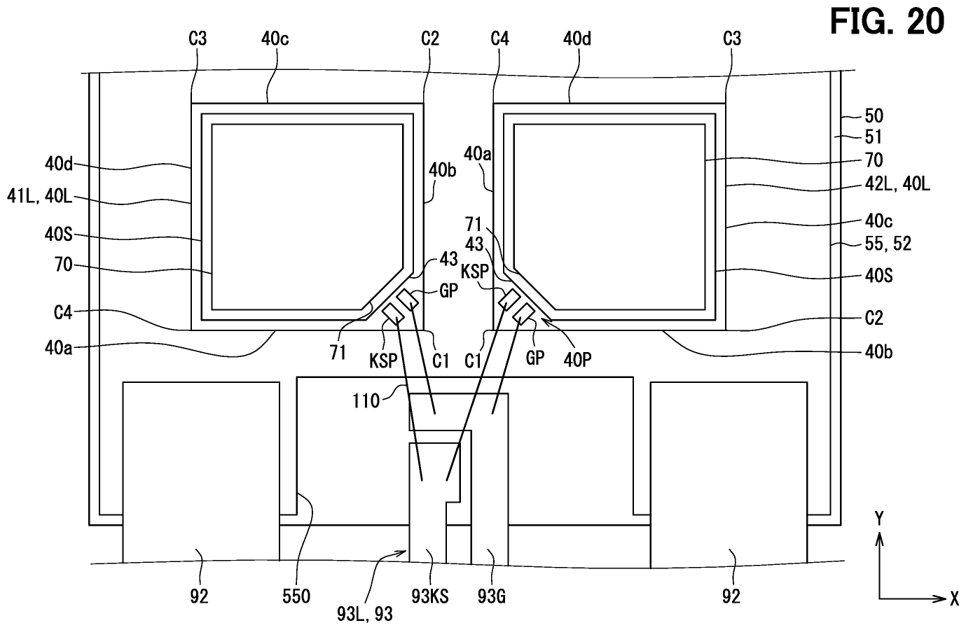

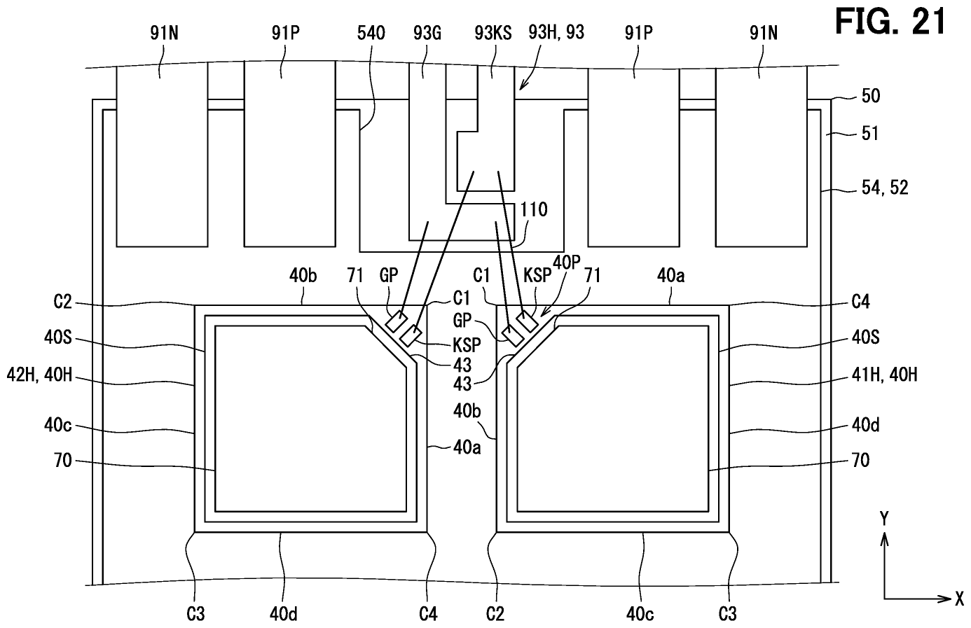

FIG. 20 illustrates, in the semiconductor device 20 according to the present embodiment, a periphery of the semiconductor elements 40L and the signal terminals 93L. FIG. 20 corresponds to FIG. 12. FIG. 21 illustrates, in the semiconductor device 20, a periphery of the semiconductor elements 40H and the signal terminals 93H. FIG. 21 corresponds to FIG. 13.

As illustrated in FIGS. 20 and 21, the notches 43 of the source electrodes 40S are provided correspondingly to the corner portions C1. Each of the notches 43 has a substantially triangular planar shape. A bottom side of each of the notches 43 connects the side portion 40a and the side portion 40b. The bottom side of the notch 43 is an inclined side which is inclined with respect to each of the side portions 40a and 40b. Each of the source electrodes 40S has a shape obtained by notching one of four corners of a substantially rectangular planar shape. Each of the conductive spacers 70 also has a planar shape corresponding to the source electrode 40S. The conductive spacer 70 has a chamfered portion 71 corresponding to the notch 43. The conductive spacer 70 has a shape obtained by chamfering one of four corners of a substantially rectangular planar shape.

As illustrated in FIG. 20, placement of the two semiconductor elements 40L (41L and 42L) arranged in the X-direction is the same as that in the configuration (see FIG. 12) described in the preceding embodiment. The semiconductor element 42L is placed in the position resulting from the 90-degree rotation from the position of the semiconductor element 41L. The side portion 40b of the semiconductor element 41L and the side portion 40a of the semiconductor element 42L face each other in the X-direction. In addition, the corner portions C1 face each other in the X-direction. Each of the semiconductor elements 40L has the two pads 40P. Specifically, in each of the semiconductor elements 40L, the pads 40P include the gate pad GP and the Kelvin source pad KSP. The two pads 40P are arranged along the inclined surface of the notch 43.

The semiconductor device 20 includes the two signal terminals 93L. The signal terminals 93L include the gate terminal 93G and the Kelvin source terminal 93KS correspondingly to the pads 40P. A structure of the two signal terminals 93L (93G and 93KS) is the same as the configuration described in the preceding embodiment. In the X-direction, the signal terminals 93L have portions located between the side portion 40b of the semiconductor element 41L and the side portion 40a of the semiconductor element 42L. The gate pads GP of the individual semiconductor elements 41L and 42L are connected to the gate terminal 93G via the bonding wires 110. The Kelvin source pads KSP of the individual semiconductor elements 41L and 42L are connected to the Kelvin source terminal 93KS via the bonding wires 110. All the bonding wires 110 connected to the semiconductor element 41L cross the side portion 40a corresponding to a side facing the signal terminals 93L in the plan view. All the bonding wires 110 connected to the semiconductor element 42L cross the side portion 40b corresponding to the side facing the signal terminals 93L in the plan view.

As illustrated in FIG. 21, placement of the two semiconductor elements 40H (41H and 42H) arranged in the X-direction is the same as that in the configuration (see FIG. 13) described in the preceding embodiment. The semiconductor element 42H is placed in the position resulting from the 90-degree rotation from the position of the semiconductor element 41H. The side portion 40b of the semiconductor element 41H and the side portion 40a of the semiconductor element 42H face each other in the X-direction. In addition, the corner portions C1 face each other in the X-direction. In each of the semiconductor elements 40H, the pads 40P include the gate pad GP and the Kelvin source pad KSP. The two pads 40P are arranged along the inclined surface of the notch 43.

The semiconductor device 20 includes the two signal terminals 93H, in the same manner as in the preceding embodiment. The signal terminals 93H include the gate terminal 93G and the Kelvin source terminal 93KS. In the X-direction, the signal terminals 93H have portions located between the side portion 40b of the semiconductor element 41H and the side portion 40a of the semiconductor element 42H. The gate pads GP of the individual semiconductor elements 41H and 42H are connected to the gate terminal 93G via the bonding wires 110. The Kelvin source pads KSP of the individual semiconductor elements 41H and 42H are connected to the Kelvin source terminal 93KS via the bonding wires 110.

All the bonding wires 110 connected to the semiconductor element 41H cross the side portion 40a corresponding to a side facing the signal terminals 93H in the plan view. All the bonding wires 110 connected to the semiconductor element 42H cross the side portion 40b corresponding to the side facing the signal terminals 93H in the plan view. The other configurations of the semiconductor device 20 are the same as the configurations described in the preceding embodiment.

### Summation of Second Embodiment

In the present embodiment, the notch 43 is provided in the portion of the four corners of each of the source electrodes 40S corresponding to the corner portion C1. This can further shorten a length (width W1) of the region where the pads 40P are arranged in the X-direction. Accordingly, it is possible to reduce the dead spaces DS of the circuit substrate 13.

In the present embodiment, the pads 40P are arranged along the inclined side of the notch 43 of each of the source electrodes 40S. As a result, even in the position resulting from the 90-degree rotation, it is possible to inhibit the pads 40P from being further away from the signal terminals 93 in the Y-direction. Accordingly, it is possible to shorten the length of each of the bonding wires 110. Particularly in the parallel connection structure of the semiconductor elements 40, it is possible to reduce variation in length of each of the bonding wires 110 connecting the gate pads GP and the gate terminal 93G.

In the present embodiment, correspondingly to the notched shape of each of the source electrodes 40S, the conductive spacer 70 has the chamfered portion 71. By adopting a chamfered structure, it is possible to increase dimensional precision of the conductive spacers 70 compared to that in the structure described in the preceding embodiment. Therefore, it is possible to suppress variation in size of each of junction surfaces of the conductive spacers 70 and consequently suppress variation in thickness of each of the joining materials 101 and 102.

### Third Embodiment

This embodiment is one of modifications of the preceding embodiment as a basic configuration and may incorporate description of the preceding embodiment. In the preceding embodiment, the pads 40P are provided to be arranged along the inclined surfaces of the notches 43. Instead of this, the pads 40P may also be provided to be arranged along the side portions 40a and the side portions 40b.

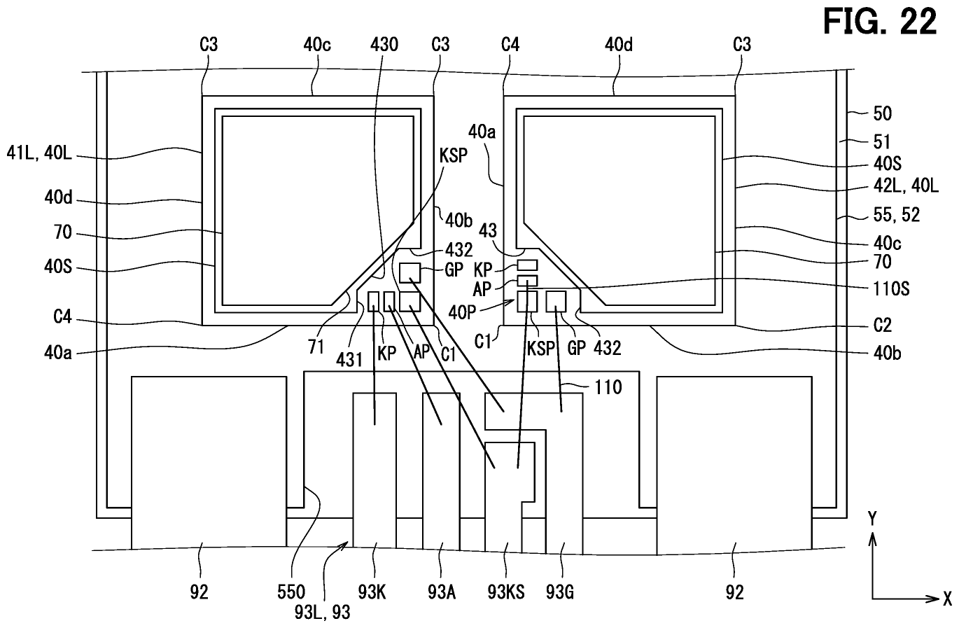

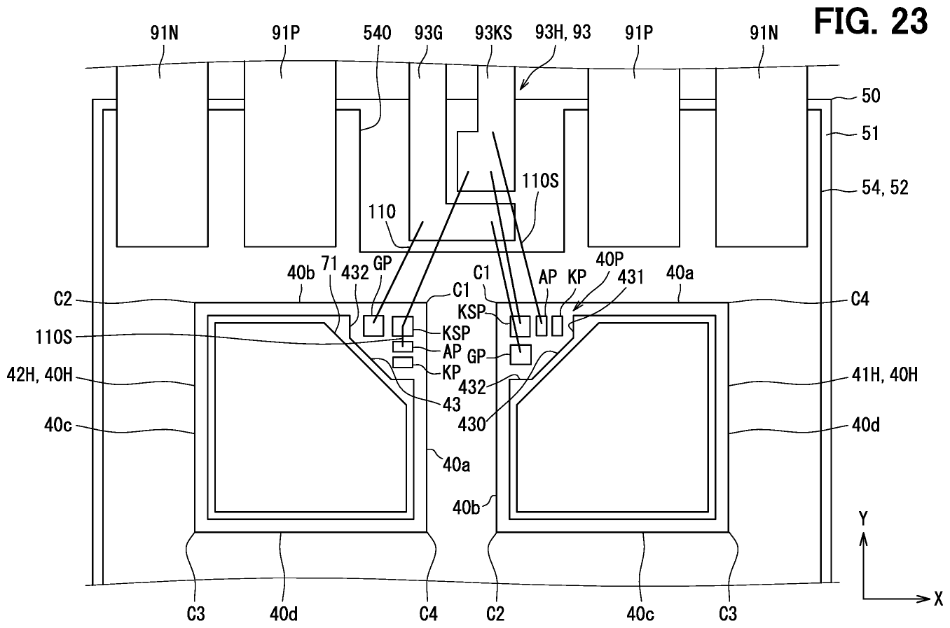

FIG. 22 illustrates a periphery of the semiconductor elements 40L and the signal terminals 93L in the semiconductor device 20 according to the present embodiment. FIG. 22 corresponds to FIG. 12. FIG. 23 illustrates a periphery of the semiconductor elements 40H and the signal terminals 93H in the semiconductor device 20. FIG. 23 corresponds to FIG. 13.

In the present embodiment also, in the same manner as in the configuration (see FIGS. 20 and 21) described in the preceding embodiment, the notches 43 of the source electrodes 40S are provided correspondingly to the corner portions C1. A bottom side of each of the notches 43 connects the side portion 40a and the side portion 40b. The bottom side of the notch 43 includes an inclined side 430 which is inclined with respect to each of the side portions 40a and 40b. In the present embodiment, a portion of the bottom side serves as the inclined side 430. To gain an area of each of the source electrodes 40S, both end portions of the bottom side are substantially parallel to the side portions 40a and 40b. Specifically, an end portion 431 on the side portion 40a side is substantially parallel to the side portion 40b. An end portion 432 on the side portion 40b side is substantially parallel to the side portion 40a. Each of the conductive spacers 70 has the chamfered portion 71 corresponding to the inclined side 430 of the notch 43, in the same manner as in the preceding embodiment.

As illustrated in FIG. 22, placement of the two semiconductor elements 40L (41L and 42L) arranged in the X-direction is the same as that in the configuration (see FIG. 12) described in the preceding embodiment. The semiconductor element 42L is placed in the position resulting from the 90-degree rotation from the position of the semiconductor element 41L. The side portion 40b of the semiconductor element 41L and the side portion 40a of the semiconductor element 42L face each other in the X-direction. In addition, the corner portions C1 face each other in the X-direction. Each of the semiconductor elements 40L has the four pads 40P. Specifically, in each of the semiconductor elements 40L, the pads 40P include the gate pad GP, the Kelvin source pad KSP, the anode pad AP, and the cathode pad KP in the same manner as in the first embodiment.

In the present embodiment, in the X-direction, the Kelvin source pad KSP, the anode pad AP, and the cathode pad KP are arranged in this order from the corner portion C1 side. These three pads 40P are arranged along the side portion 40a. Meanwhile, in the Y-direction, the Kelvin source pad KSP and the gate pad GP are arranged in this order from the corner portion C1 side. These two pads 40P are arranged along the side portion 40b. Thus, the four pads 40P are arranged in a substantially letter-L planar shape in which the Kelvin source pad KSP is placed on a corner portion. Each of the anode pad AP and the cathode pad KP has a substantially rectangular planar shape in which a length of a side substantially parallel to the side portion 40b is larger than a length of a side substantially parallel to the side portion 40a. Each of the gate pad GP and the Kelvin source pad KSP has a substantially square planar shape in which a length of a side is substantially equal to a long side of the anode pad AP.

The semiconductor device 20 includes the four signal terminals 93L in the same manner as in the configuration (FIG. 12) described in the preceding embodiment. The signal terminals 93L include the gate terminal 93G, the Kelvin source terminal 93KS, the anode terminal 93A, and the cathode terminal 93K. Each of the signal terminals 93L has the same structure as that in the configuration described in FIG. 12. In the X-direction, the signal terminals 93L have portions located between the side portion 40b of the semiconductor element 41L and the side portion 40a of the semiconductor element 42L. The gate pads GP of the individual semiconductor elements 41L and 42L are connected to the gate terminal 93G via the bonding wires 110. The Kelvin source pads KSP of the individual semiconductor elements 41L and 42L are connected to the Kelvin source terminal 93KS via the bonding wires 110.

In the semiconductor element 41L, the anode pad AP is connected to the anode terminal 93A via the bonding wire 110, while the cathode pad KP is connected to the cathode terminal 93K via the bonding wire 110. In the semiconductor element 42L, the anode pad AP is connected to the Kelvin source pad KSP located adjacent thereto via the bonding wire 110S. To the cathode pad KP, neither of the bonding wires 110 and 110S is connected. The bonding wires 110 connected to the semiconductor element 41L have portions crossing the side portion 40a corresponding to a side facing the signal terminals 93L in the plan view. All the bonding wires 110 connected to the semiconductor element 42L cross the side portion 40b corresponding to the side facing the signal terminals 93L in the plan view.

As illustrated in FIG. 23, placement of the two semiconductor elements 40H (41H and 42H) arranged in the X-direction is the same as that in the configuration (see FIG. 13) described in the preceding embodiment. The semiconductor element 42H is placed in the position resulting from the 90-degree rotation from the position of the semiconductor element 41H. The side portion 40b of the semiconductor element 41H and the side portion 40a of the semiconductor element 42H face each other in the X-direction. In addition, the corner portions C1 face each other in the X-direction. Each of the semiconductor elements 40H has the four pad 40P, similarly to each of the semiconductor elements 40L. An arrangement of the four pads 40P is the same as that of the pads 40P of the semiconductor element 40L.

The semiconductor device 20 includes the two signal terminals 93H, in the same manner as in the preceding embodiment. The signal terminals 93H include the gate terminal 93G and the Kelvin source terminal 93KS. In the X-direction, the signal terminals 93H have portions located between the side portion 40b of the semiconductor element 41H and the side portion 40a of the semiconductor element 42H. The gate pads GP of the individual semiconductor elements 41H and 42H are connected to the gate terminal 93G via the bonding wires 110. The Kelvin source pads KSP of the individual semiconductor elements 41H and 42H are connected to the Kelvin source terminal 93KS via the bonding wires 110.

The anode pad AP of the semiconductor element 41H is connected to the Kelvin source terminal 93KS via the bonding wire 110, while the anode pad AP of the semiconductor element 42H is connected to the Kelvin source pad KSP via the bonding wire 110S. To the cathode pad KP of each of the semiconductor elements 40H, neither of the bonding wires 110 and 110S is connected. All the bonding wires 110 connected to the semiconductor element 41H cross the side portion 40a corresponding to a side facing the signal terminals 93H in the plan view. All the bonding wires 110 connected to the semiconductor element 42H cross the side portion 40b corresponding to the side facing the signal terminals 93H in the plan view. The other configurations of the semiconductor device 20 are the same as the configurations described in the preceding embodiment.

### Summation of Third Embodiment

In the present embodiment, the plurality of pads 40P are arranged side by side along the side portions 40a and 40b to define a substantially L-shaped planar shape. This allows a larger number of the pads 40P to be arranged in notched portions corresponding to the notches 43 including the inclined sides 430.

In the present embodiment, of the four pads 40P, the gate pad GP and the Kelvin source pad KSP are connected to the signal terminals 93 via the bonding wires 110 in, e.g., each of the two semiconductor elements 40L. The anode pad AP and the cathode pad KP are connected to the signal terminals 93 via the bonding wires 110 only in the semiconductor element 41L. The gate pad GP and the Kelvin source pad KSP correspond to a first pad, while the anode pad AP corresponds to a second pad.

Then, in any of the semiconductor elements 40, the lengths of the gate pad GP and the Kelvin source pad KSP corresponding to the pads 40P to be connected to the signal terminals 93 are set larger than those of the anode pad AP and the cathode pad KP. The gate pad GP and the Kelvin source pad KSP have lengths along the side portion 40a and lengths along the side portion 40b which are each elongated. Specifically, the gate pad GP and the Kelvin source pad KSP are elongated in either the X-direction or the Y-direction. Accordingly, even when the gate pad GP and the Kelvin source pad KSP are placed in positions resulting from 90-degree rotation, the bonding wires 110 are easily connected thereto. This configuration may also be combined with the configurations described in the other embodiments.

### Modifications

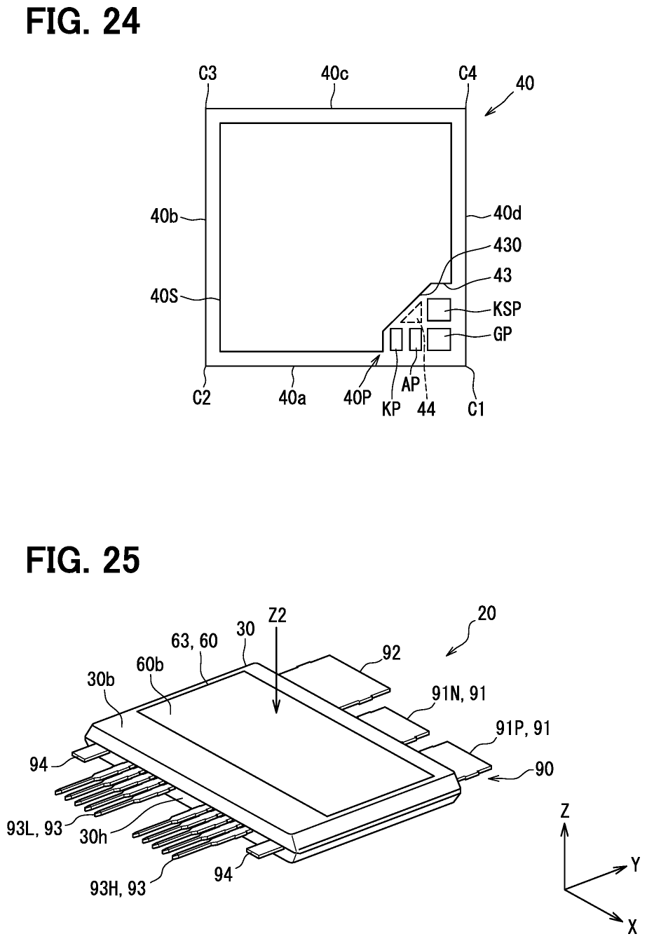

An order in which the four pads 40P are arranged is not limited to the examples described above. For example, as illustrated in FIG. 24, the gate pad GP may also be placed on a corner portion. According to this, in the two semiconductor elements 40 arranged side by side, the gate pads GP are closer to each other, and therefore it is possible to reduce variation in length of the bonding wires 110.

Alternatively, as illustrated in FIG. 24, in a pad formation region including a portion resulting from notching of the source electrode 40S and in the vicinity of the inclined side 430 of the notch 43, a temperature sensing diode 44 may also be provided. The temperature sensing diode 44 is configured to include, e.g., polysilicon doped with an impurity and an aluminum-based wiring material, and is provided on a back surface of the semiconductor substrate. This allows a vacant space between the inclined side 430 and the pads 40P arranged in a substantially L-shaped planar shape to be used, and accordingly a wide region can be provided for the source electrode 40S, i.e., the switching element. In addition, since the temperature sensing diode 44 is provided at a position close to the element formation region, even though the temperature sensing diode 44 is provided in the pad formation region, it is possible to accurately detect a temperature of the semiconductor element 40.

### Fourth Embodiment

This embodiment is one of modifications of the preceding embodiment as a basic configuration and may incorporate description of the preceding embodiment. In the preceding embodiment, of the first element and the second element that are connected in parallel, the second element is placed in the position resulting from the 90-degree rotation from that of the first element. Instead of this, it may also be possible that, of the first element and the second element that are not connected in parallel, the second element is placed in a position resulting from 90-degree rotation from that of the first element. Each of the arms may also be configured to include the one semiconductor element 40, instead of the plurality of semiconductor elements 40. Instead of using the configuration in which the signal terminals 93H and 93L are arranged such that the semiconductor elements 40 are interposed therebetween, it may also be possible to arrange the signal terminals 93H and the signal terminal 93L side by side.

### Semiconductor Device

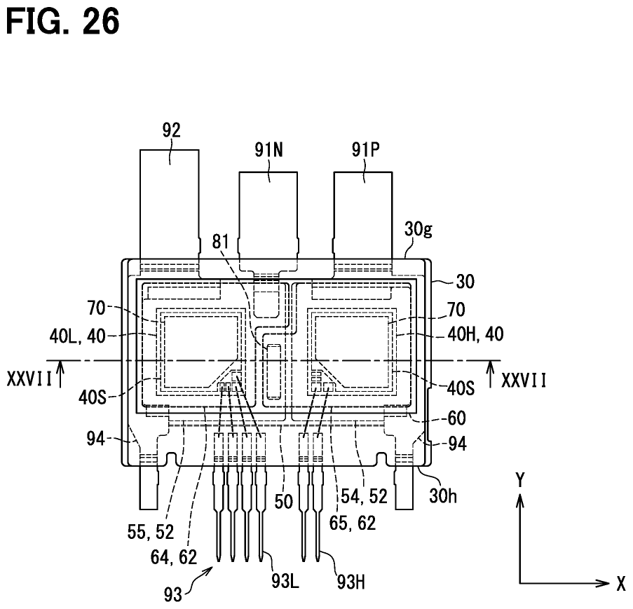

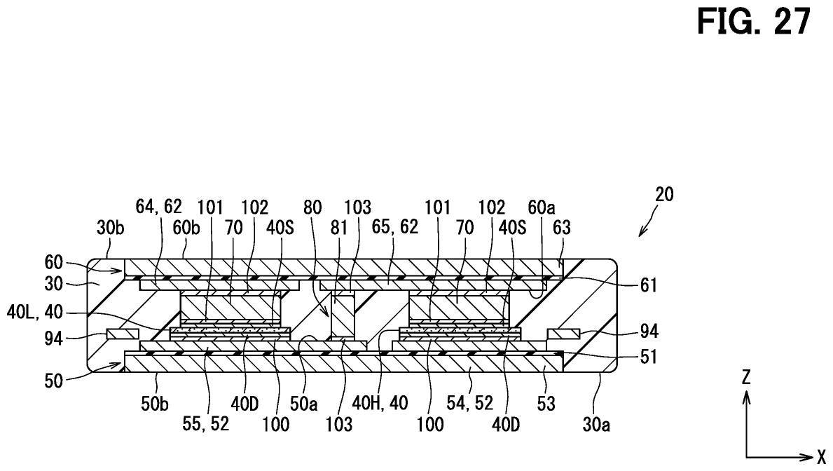

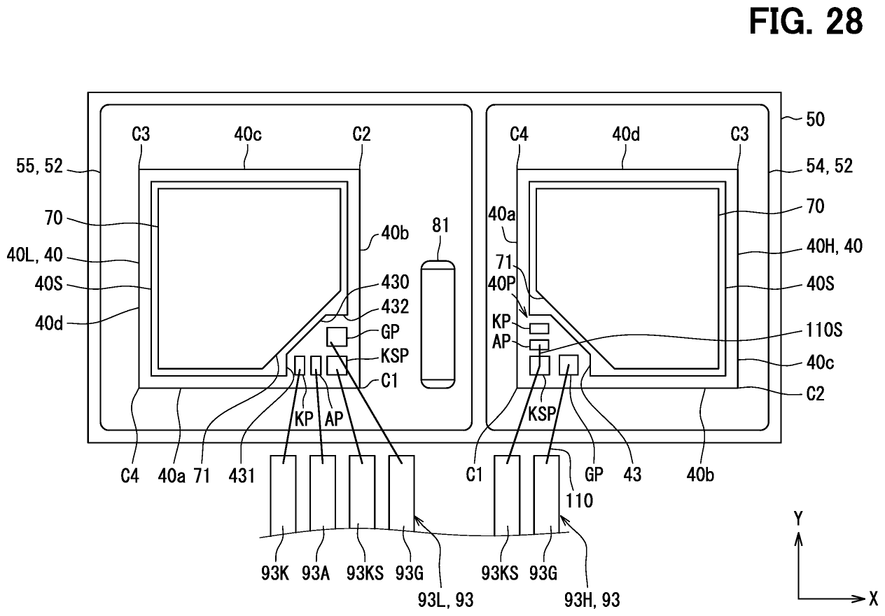

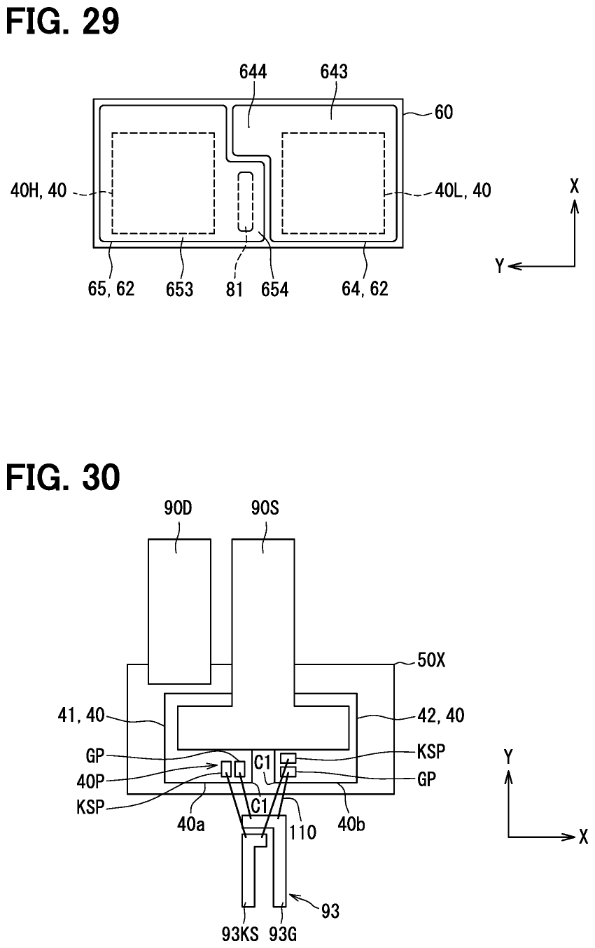

On the basis of FIGS. 25 to 29, a description will be given of the semiconductor device 20 in the present embodiment. FIG. 25 is a perspective view of the semiconductor device 20. FIG. 26 is a plan view obtained by viewing FIG. 25 from a Z2-direction. FIG. 26 is a transparent view illustrating an inner structure. FIG. 27 is a cross-sectional view along a line XXVII-XXVII in FIG. 26. FIG. 28 illustrates a circuit pattern of the substrate 50, while illustrating placement of the semiconductor elements 40, an arrangement of the signal terminals 93, and connection structures between the semiconductor elements 40 and the signal terminals 93. FIG. 29 illustrates a circuit pattern of the substrate 60. In FIG. 29, the semiconductor elements 40 and the joint portion 81 are indicated by broken lines.

In the same manner as in the preceding embodiments, the semiconductor device 20 in the present embodiment forms one of the upper/lower arm circuits 9, i.e., the upper/lower arm circuit 9 corresponding to one phase. The semiconductor device 20 includes the same components as those of the configuration (see FIGS. 2 to 13 described in the preceding embodiment. The semiconductor device 20 includes the sealing body 30, the semiconductor elements 40, the substrates 50 and 60, conductive spacers 70, an arm connection portion 80, and external connection terminals 90. A description will be given below of portions different from those of the configuration described in the preceding embodiment.

In the same manner as in the preceding embodiment, the sealing body 30 seals some of the other components included in the semiconductor device 20. As illustrated in FIG. 25, the sealing body 30 has a substantially rectangular planar shape. The sealing body 30 has the one surface 30a and the back surface 30b in the Z-direction. Side surfaces connecting the one surface 30a and the back surface 30b include two side surfaces 30g and 30h from which the external connection terminals 90 protrude. The side surface 30h is a surface opposite to the side surface 30g in the Y-direction.

The semiconductor elements 40 include the one semiconductor element 40H forming the upper arm 9H and the semiconductor element 40L forming the lower arm 9L. The semiconductor device 20 includes the two semiconductor elements 40. The semiconductor elements 40H and 40L have configurations common to each other. As illustrated in FIG. 26, the semiconductor elements 40H and 40L are arranged in the X-direction serving as the first direction. The individual semiconductor elements 40 are placed at locations substantially equal to each other in the Z-direction. The individual semiconductor elements 40 have the respective drain electrodes 40D facing the substrate 50. The individual semiconductor elements 40 have the respective source electrodes 40S facing the substrate 60.

The substrates 50 and 60 are arranged in the Z-direction so as to have the plurality of semiconductor elements 40 interposed therebetween. The substrates 50 and 60 are arranged so as to have at least respective portions thereof facing each other in the Z-direction. The substrates 50 and 60 include all of the plurality of semiconductor elements 40 (40H and 40L) in the plan view.

In the same manner as in the preceding embodiment, the substrate 50 includes the insulating base material 51, the top surface metal body 52, and the back surface metal body 53. The substrate 60 has the insulating base material 61, the top surface metal body 62, and the back surface metal body 63. The top surface metal body 52 has the P-wiring 54 and the relay wiring 55. The P-wiring 54 and the relay wiring 55 are electrically isolated from each other by a predetermined space (gap).

The P-wiring 54 is connected to each of the P-terminal 91P and the drain electrode 40D of the semiconductor element 40H. The P-wiring 54 electrically connects the P-terminal 91P and the drain electrode 40D of the semiconductor element 40H. The P-wiring 54 has a substantially rectangular planar shape having the Y-direction as the longitudinal direction. The relay wiring 55 is connected to each of the drain electrode 40D of the semiconductor element 40L, the arm connection portion 80, and the output terminal 92. The relay wiring 55 has a substantially rectangular planar shape. The relay wiring 55 relates to a first conductor, while the P-wiring 54 corresponds to a second conductor.

The P-wiring 54 and the relay wiring 55 are arranged side by side in the X-direction. The semiconductor element 40L is mounted offset to one end side of the relay wiring 55 in the X-direction, specifically to a side distant from the P-wiring 54. The joint portion 81 included in the arm connection portion 80 is mounted offset to another end side of the relay wiring 55 in the X-direction, specifically to a side close to the P-wiring 54. The P-terminal 91P is connected to the vicinity of one end of the P-wiring 54 in the Y-direction. The output terminal 92 is connected to the vicinity of one end of the relay wiring 55 in the Y-direction. The P-terminal 91P and the output terminal 92 are placed on the same side of the semiconductor elements 40 in the Y-direction.

The top surface metal body 62 has the N-wiring 64 and the relay wiring 65. The N-wiring 64 and the relay wiring 65 are electrically isolated from each other by a predetermined space (gap). The N-wiring 64 is connected to each of the N-terminal 91N and the source electrode 40S of the semiconductor element 40L. The relay wiring 65 electrically connects the source electrodes 40S of the semiconductor elements 40H and the arm connection portion 80.

The N-wiring 64 has a base portion 643 and an extending portion 644. The N-wiring 64 has a substantially L-shaped planar shape. The base portion 643 has a substantially rectangular planar shape. The base portion 643 includes the semiconductor element 40L in the plan view. The extending portion 644 is continued to one of sides of the base portion 643 having a substantially rectangular planar shape. The extending portion 644 extends from the side of the base portion 643 facing the relay wiring 65 toward a base portion 653 in the X-direction.

The relay wiring 65 has the base portion 653 and an extending portion 654. The relay wiring 65 has a substantially letter-L planar shape. The base portion 653 has a substantially rectangular planar shape. The base portion 653 includes the semiconductor element 40H in the plan view. The extending portion 654 is continued to one of sides of the base portion 653 having the substantially rectangular planar shape. The extending portion 654 extends from the side of the base portion 653 facing the N-wiring 64 toward the base portion 643 in the X-direction. The extending portion 654 has at least a portion overlapping the relay wiring 55 in the plan view.

The N-wiring 64 and the relay wiring 65 are arranged side by side in the X-direction. The base portions 643 and 653 are arranged in the X-direction. The source electrode 40S of the semiconductor element 40L is electrically connected to the base portion 643. The source electrode 40S of the semiconductor element 40H is electrically connected to the base portion 653. The extending portions 644 and 654 are arranged in the Y-direction. The N-terminal 91N is connected to the extending portion 644. The joint portion 81 is connected to the extending portion 654.

The conductive spacers 70 are interposed between the source electrodes 40S of the semiconductor elements 40 and the substrate 60. The conductive spacers 70 are individually connected to the source electrodes 40S of the semiconductor elements 40.

The arm connection portion 80 electrically connects the relay wiring 55 and the relay wiring 65. The arm connection portion 80 is provided between the semiconductor element 40H and the semiconductor element 40L in the X-direction. In the plan view, the arm connection portion 80 is provided in a region where the relay wiring 55 and the relay wiring 65 (extending portion 654) overlap each other. The arm connection portion 80 in the present embodiment is configured to include the joint portion 81 and the joining material 103, in the same manner as in the preceding embodiment. The joint portion 81 is a metal prismatic body. In the Z-direction, between one of end portions of the joint portion 81 and the relay wiring 55, the joining material 103 is interposed and, between another of the end portions and the relay wiring 65, the joining material 103 is interposed. Instead of this, the joint portion 81 may also be integrally continued to at least one of the top surface metal bodies 52 and 62. The arm connection portion 80 may also be configured not to include the joint portion 81.

The external connection terminals 90 include the power source terminals 91, the output terminals 92, and the signal terminals 93. The power source terminals 91 include the P-terminals 91P and the N-terminals 91N. In the following, the P-term inal 91P, the N-terminal 91N, and the output terminal 92 may be referred to also as the main terminals 91P, 91N, and 92. The signal terminals 93 include the signal terminal 93H on the upper arm 9H side and the signal terminal 93L on the lower arm 9L side.

Each of the P-terminals 91P is connected to the vicinity of one end of the P-wiring 54 in the Y-direction. The P-terminal 91P extends outward from the connection portion with the P-wiring 54 in the Y-direction. The P-terminal 91P has a portion covered with the sealing body 30 and the remaining portion protruding from the sealing body 30. The P-terminal 91P protrudes from the vicinity of a middle of the side surface 30g in the Z-direction to the outside of the sealing body 30.

Each of the N-terminals 91N is connected to the vicinity of one end of the N-wiring 64 in the Y-direction. The N-terminal 91N extends outward from the connection portion with the N-wiring 64 in the Y-direction. The N-terminal 91N has a portion covered with the sealing body 30 and the remaining portion protruding from the sealing body 30. The N-terminal 91N protrudes from the vicinity of the middle of the side surface 30g in the Z-direction to the outside of the sealing body 30.

Each of the output terminals 92 is connected to the vicinity of one end of the relay wiring 55 in the Y-direction. The output terminal 92 extends outward from a connection portion with the relay wiring 55 in the Y-direction. The output terminal 92 has a portion covered with the sealing body 30 and the remaining portion protruding from the sealing body 30. The output terminal 92 protrudes from the vicinity of the middle of the side surface 30g in the-Z direction to the outside of the sealing body 30.

The three main terminals 91P, 91N, and 92 are arranged side by side in the X-direction. The main terminals 91P, 91N, and 92 are arranged in the X-direction in order of the P-terminal 91P, the N-terminal 91N, and the output terminal 92. The P-term inal 91P and the N-terminal 91N each serving as the power source terminal 91 have side portions facing each other at parts including the portions protruding from the sealing body 30.

The signal terminals 93 are connected to the pads 40P of the corresponding semiconductor elements 40 via connection members such as the bonding wires 110. The signal terminals 93H are connected to the pads 40P of the semiconductor element 40H via the bonding wires 110. The signal terminals 93L are connected to the pads 40P of the semiconductor element 40L via the bonding wires 110. The signal terminals 93 extend outward in the Y-direction to protrude from the vicinity of a middle of the side surface 30h in the Z-direction to the outside of the sealing body 30. The signal terminals 93 extend on the side opposite to the main terminals 91P, 91N, and 92 in the Y-direction. In the Y-direction, between the main terminals 91P, 91N, and 92 and the signal terminals 93, the semiconductor elements 40 are placed.

The semiconductor device 20 includes two guide frames 94. One of the guide frames 94 is continued to the P-terminal 91P. Another of the guide frames 94 is continued to the output terminal 92. These guide frames 94 are portions connecting a peripheral frame holding the signal terminals 93 and the main terminals 91P and 92 in a state before unneeded portions of a lead frame are removed. The guide frame 94 continued to the p-terminal 91P has a portion connected to the P-wiring 54. The portion of the guide frame 94 continued to the output terminal 92 is connected to the relay wiring 55. The guide frame 94 can have the same connection structure (junction structure) as that of each of the main terminals 91P, 91N, and 92.

As described above, in the semiconductor device 20 in the present embodiment, the sealing body 30 seals the plurality of semiconductor elements included in the upper/lower arm circuit 9 corresponding to one phase. The sealing body 30 integrally seals the plurality of semiconductor elements 40, a portion of the substrate 50, a portion of the substrate 60, the plurality of conductive spacers 70, the arm connection portion 80, and a portion of each of the external connection terminals 90. The sealing body 30 seals the insulating base materials 51 and 61 and the top surface metal bodes 52 and 62 over the substrates 50 and 60.

The semiconductor elements 40 are placed between the substrates 50 and 60 in the Z-direction. The semiconductor elements 40 are interposed between the substrates 50 and 60 placed to face each other. This allows heat in the semiconductor elements 40 to be dissipated on both sides in the Z-direction. The semiconductor device 20 has a double-sided heat dissipation structure. The back surface 50b of the substrate 50 is substantially flush with the one surface 30a of the sealing body 30. The back surface 60b of the substrate 60 is substantially flush with the back surface 30b of the sealing body 30. Since the back surfaces 50b and 60b are exposed surfaces, it is possible to increase a heat dissipation property.

### Arrangement of Pads

Next, on the basis of FIG. 28, a description will be given of an arrangement of the pads 40P, an arrangement of the signal terminals 93, and connection structures between the semiconductor elements 40 and the signal terminals 93.

As illustrated in FIG. 28, the notches 43 of the source electrodes 40S are provided correspondingly to the corner portions C1, in the same manner as in the configuration (see FIG. 22) described in the preceding embodiment. The bottom side of each of the notches 43 includes the inclined side 430 that is inclined with respect to each of the side portions 40a and 40b. In the present embodiment, the inclined side 430 corresponds to a portion of the bottom side. Of the bottom side, the end portion 431 on the side portion 40a side is substantially parallel to the side portion 40b. An end portion 432 on the side portion 40b side is substantially parallel to the side portion 40a. Each of the conductive spacers 70 has the chamfered portion 71 corresponding to the inclined side 430 of the notch 43, in the same manner as in the preceding embodiment.

The placement of the two semiconductor elements 40 (40H and 40L) arranged in the X-direction is the same as that in the configuration (see FIG. 22) described in the preceding embodiment. The semiconductor element 40H is placed in a position resulting from 90-degree rotation from a position of the semiconductor element 40L. The side portion 40b of the semiconductor element 40L and the side portion 40a of the semiconductor element 40H face each other in the X-direction. In addition, the corner portions C1 face each other in the X-direction. In the Y-direction corresponding to the second direction, the side portion 40a of the semiconductor element 40L and the side portion 40b of the semiconductor element 40H correspond to sides facing the juxtaposed signal terminals 93. Of the two semiconductor elements 40 arranged side by side, the semiconductor element 40L corresponds to the first element, and the semiconductor element 40H corresponds to the second element.

The pads 40P have the same configuration as that described in the third embodiment. In other words, each of the semiconductor elements 40 has the four pads 40P. The pads 40P include the gate pad GP, the Kelvin source pad KSP, the anode pad AP, and the cathode pad KP. In the X-direction, the Kelvin source pad KSP, the anode pad AP, and the cathode pad KP are arranged in this order from the corner portion C1 side. These three pads 40P are arranged along the side portion 40a. Meanwhile, in the Y-direction, the Kelvin source pad KSP and the gate pad GP are arranged in this order from the corner portion C1 side. These two pads 40P are arranged along the side portion 40b.

The four pads 40P are arranged in a substantially letter-L planar shape in which the Kelvin source pad KSP is placed on the corner portion. Each of the anode pad AP and the cathode pad KP has a substantially rectangular planar shape in which a length of a side substantially parallel to the side portion 40b is larger than a length of a side substantially parallel to the side portion 40a. Each of the gate pad GP and the Kelvin source pad KSP has a substantially square planar shape in which a length of a side is substantially equal to a long side of the anode pad AP.

The semiconductor device 20 includes the four signal terminals 93L and the two signal terminals 93H. The signal terminals 93L include a gate terminal 93G, a Kelvin source terminal 93KS, an anode terminal 93A, and a cathode terminal 93K. The signal terminals 93H include the gate terminal 93G and the Kelvin source terminal 93KS. The six signal terminals 93 are arranged side by side in the X-direction. Specifically, the gate terminal 93G as the signal terminal 93H, the Kelvin source terminal 93KS as the signal terminal 93H, the gate terminal 93G as the signal terminal 93L, the Kelvin source terminal 93KS as the signal terminal 93L, the anode terminal 93A as the signal terminal 93L, and the cathode terminal 93K as the signal terminal 93L are arranged in this order. The six signal terminals 93 correspond to the juxtaposed terminals. Each of the signal terminals 93L corresponds to a first terminal connected to the first element, while each of the signal terminals 93H corresponds to a second terminal connected to the second element.

In the X-direction, the signal terminals 93 have portions located between the side portion 40b of the semiconductor element 40L and the side portion 40a of the semiconductor element 40H. In the semiconductor element 40L, the gate pad GP is connected to the corresponding gate terminal 93G via the bonding wire 110. The Kelvin source pad KSP is connected to the corresponding Kelvin source terminal 93KS via the bonding wire 110. The anode pad AP is connected to the anode terminal 93A via the bonding wire 110. The cathode pad KP is connected to the cathode terminal 93K via the bonding wire 110. All the bonding wires 110 connected to the semiconductor element 40L cross the side portion 40a corresponding to the side facing the signal terminals 93 in the plan view.

In the semiconductor element 40H, the gate pad GP is connected to the corresponding gate terminal 93G via the bonding wire 110. The Kelvin source pad KSP is connected to the corresponding Kelvin source terminal 93KS via the bonding wire 110. The anode pad AP is connected to the Kelvin source pad KSP located adjacent thereto via the bonding wire 110S. To the cathode pad KP, neither of the bonding wires 110 and 110S is connected. All the bonding wires 110 connected to the semiconductor element 40H cross the side portion 40b corresponding to the side facing the signal terminals 93 in the plan view.

### Summation of Fourth Embodiment

In the present embodiment, the semiconductor elements 40H and 40L arranged side by side in the X-direction have the structures common to each other. In the common structures, the pads 40P are provided offset to the periphery of the corner portions C1. The semiconductor element 40L is placed such that the side portion 40a faces the signal terminals 93 in the Y-direction and that the side portion 40b faces the semiconductor element 40H in the X-direction. The semiconductor element 40H is placed in the position resulting from the 90-degree rotation from the position of the semiconductor element 40L such that the side portion 40b faces the signal terminals 93 in the Y-direction and that the side portion 40a faces the semiconductor element 40L in the X-direction. Due to the placement of the semiconductor elements 40H and 40L described above, the pad arrangement regions of the two semiconductor elements 40H and 40L are shortened in the X-direction. Since the pad arrangement regions are shortened, regions where the plurality of signal terminals 93 are arranged can be shortened in the X-direction. Accordingly, in the circuit substrate 13, the dead spaces DS resulting from the signal terminals 93 can be reduced. It is possible to suppress degradation of reliability related to the bonding wires 110, while reducing the dead spaces DS. Besides, it is possible to achieve effects equal to the effects described in the preceding embodiments with respect to configurations identical or similar to those in the preceding embodiments, though a description thereof is omitted.

According to the present embodiment, the signal terminals 93H and 93L are juxtaposed. As a result, even though the signal terminals 93H and 93L are not bent, it is possible to achieve connection to the circuit substrate 13.

An example in which the arrangement of the pads 40P is configured as described in the third embodiment has been described, but the configuration is not limited thereto. Combinations with the configurations described in the first embodiment, the second embodiment, and the modifications are also possible.

### Other Embodiments

The disclosure in the description, drawings, and the like is not limited to the exemplified embodiments. The disclosure encompasses the exemplified embodiments and modifications made based thereon by those skilled in the art. For example, the disclosure is not limited to the combinations of parts and/or elements shown in the embodiments. The disclosure can be implemented in various combinations. The disclosure can have additional components that can be added to the embodiments. The disclosure covers omissions of parts and/or elements of the embodiments. The disclosure covers replacement or combination of parts and/or elements between one of the embodiments and another thereof. The disclosed technical scope is not limited to the description of the embodiments. The several technical scopes disclosed are indicated by the description of the claims, and should be construed to include all modifications within the meaning and scope equivalent to the description of the claims.

The disclosure in the description, drawings and the like is not limited by the description of the claims. The disclosures in the description, the drawings, and the like encompass the technical ideas described in the claims, and further extend to a wider variety of technical ideas than those in the claims. Therefore, various technical ideas can be extracted from the disclosure of the description, the drawings and the like without being limited to the description of the claims.

When an element or a layer is described as “located above”, “coupled”, “connected,” or “combined”, the element or the layer may be directly located above, coupled to, connected to, or combined with another element or another layer, or an intervening element or intervening layer may be present. By contrast, when an element or a layer is described as “located directly above”, “directly coupled to”, “directly connected to”, or “directly combined with” another element or layer, no intervening element or no intervening layer is present. Other terms used to describe relationships between elements (for example, “between” versus “directly between” and “adjacent” versus “directly adjacent”) should be similarly construed. When used in the description, the term “and/or” includes any combination and all combinations related to one or more of the related listed items.

Spatially relative terms such as “inside”, “outside”, “back”, “bottom”, “low”, “upper”, “high” are used herein to facilitate the description that describes relationships between one element or feature and another element or feature. The spatially relative terms can be intended to include different orientations of a device in use or operation, in addition to the orientations depicted in the drawings. For example, when the device in the drawing is flipped over, an element or feature described as “below” or “directly below” another element or feature is directed “above” the other element or feature. Therefore, the term “below” can include both upward and downward orientations. The device may also be oriented in another direction (rotated 90 degrees or in any other direction), and spatially relative descriptors used in this description are accordingly construed.

A vehicle drive system 1 is not limited to the configuration described above. By way of example, an example in which the one motor generator 3 is included has been described, but the configuration is not limited thereto. A plurality of motor generators may also be included. An example in which the power conversion device 4 includes the inverter 6 as the power conversion circuit has been described, but the configuration is not limited thereto. For example, the configuration may be such that a plurality of inverters are included. The configuration may also be such that at least one inverter and a converter are included. Only the converter may also be included.

While an example in which the semiconductor elements 40 has the MOSFETs 11 as the switching elements has been described, the switching elements are not limited thereto. For example, IGBTs may also be adopted. The IGBT is an abbreviation of Insulated Gate Bipolar Transistor.

While an example in which the semiconductor device 20 includes the conductive spacers 70 has been described, the semiconductor device 20 is not limited thereto. For example, instead of the conductive spacers 70, protruding portions may also be provided on the top surface metal body 62.

While an example in which the substrate 50 is adopted as a wiring member to be connected to the drain electrodes 40D has been described, the wiring member is not limited thereto. In a configuration in which the wiring member is not limited to the substrate 50, instead of the substrate 50, a metal plate (lead frame) may also be adopted. While an example in which the substrate 60 is adopted as a wiring member to be connected to the source electrodes 40S has been described, the wiring member is not limited thereto. In a configuration in which the wiring member is not limited to the substrate 60, instead of the substrate 60, a metal plate (lead frame) may also be adopted. In a case of the metal plate, on the drain electrode 40D side, a first metal plate to which the drain electrode 40D of the semiconductor element 40H is to be connected and a second metal plate to which the drain electrode 40D of the semiconductor element 40L is to be connected are placed. On the source electrode 40S side, a third metal plate to which the source electrode 40S of the semiconductor element 40H is to be connected and a fourth metal plate to which the source electrode 40S of the semiconductor element 40L is to be connected are placed.

While an example in which the semiconductor device 20 has a double-sided heat dissipation structure has been described, the semiconductor device 20 is not limited thereto. As illustrated in FIG. 30, the semiconductor device 20 is also applicable to a single-sided heat dissipation structure. In the example illustrated in FIG. 30, on a metal plate serving as a wiring member 50X, the two semiconductor elements 40 (41 and 42) are arranged side by side in the X-direction. The two semiconductor elements 40 are connected in parallel to each other. In each of the semiconductor elements 41 and 42, the pads 40P are arranged offset to the corner portion C1. The semiconductor element 42 is placed in a position resulting from 90-degree rotation from a position of the semiconductor element 41. The side portion 40a of the semiconductor element 41 and the side portion 40b of the semiconductor element 42 face the juxtaposed signal terminals 93. A main terminal 90D is connected to the wiring member 50X. A main terminal 90S is connected to the source electrodes, not shown, of the two semiconductor elements 40.

What is claimed is:

1. A semiconductor device to be connected to a circuit substrate, the semiconductor device comprising:
a plurality of semiconductor elements each having a first main electrode on one surface, a second main electrode on a back surface opposite to the one surface in a plate thickness direction of the semiconductor element, and a signal pad provided at a location on the back surface different from that of the second main electrode;
a wiring member electrically connected to the first main electrode;
a plurality of signal terminals to be connected to the circuit substrate; and
a plurality of bonding wires electrically connecting the pads of the plurality of semiconductor elements and the plurality of signal terminals,
wherein each of the plurality of semiconductor elements has a rectangular shape having four corner portions and four side portions in a plan view viewed along the plate thickness direction,
wherein the plurality of semiconductor elements include a first element and a second element arranged side by side with the first element in a first direction perpendicular to the plate thickness direction,
wherein the plurality of signal terminals include a plurality of juxtaposed terminals each connected to at least one of the first element and the second element and arranged side by side in the first direction,
wherein the plurality of juxtaposed terminals are arranged side by side with the first element and the second element in a second direction perpendicular to the plate thickness direction and the first direction,
wherein the first element and the second element have structures common to each other and, in each of the first element and the second element, the pads are disposed to offset to a periphery of the first corner portion,
wherein, in the first element, the first side portion continued to the first corner portion faces the juxtaposed terminals in the second direction, and the second side portion continued to the first corner portion faces the second element in the first direction,
wherein the second element is disposed in a position resulting from 90-degree rotation from a position of the first element, and
wherein, in the second element, the second side portion continued to the first corner portion faces the juxtaposed terminals in the second direction, while the first side portion continued to the first corner portion faces the first element in the first direction.

2. The semiconductor device according to claim 1,
wherein the bonding wires connected to the first element include at least one bonding wire crossing the first side portion of the first element in the plan view, and
wherein the bonding wires connected to the second element include at least one bonding wire crossing the second side portion of the second element in the plan view.

3. The semiconductor device according to claim 1,
wherein the plurality of juxtaposed terminals include at least one juxtaposed terminal located between the second side portion of the first element and the first side portion of the second element in the first direction.

4. The semiconductor device according to claim 1,
wherein the first main electrode of the first element and the first main electrode of the second element are connected to a common conductor of the wiring member, and
wherein the first element and second element are connected in parallel.

5. The semiconductor device according to claim 4,
wherein each of the plurality of semiconductor elements has a plurality of the pads,
wherein the pads include a gate pad for a gate electrode that controls a main current flowing between the first main electrode and the second main electrode, and
wherein the gate pad is closer to the first corner portion than the other pads in each of the first element and the second element.

6. The semiconductor device according to claim 1,
wherein the wiring member has a first conductor and a second conductor electrically isolated from the first conductor,
wherein the first main electrode of the first element is connected to the first conductor, and the first main electrode of the second element is connected to the second conductor, and
wherein the juxtaposed terminals include a first terminal as the signal terminal connected to the first element and a second terminal as the signal terminal connected to the second element.

7. The semiconductor device according to claim 1,
wherein the second main electrode has a notch provided correspondingly to the first corner portion and including an inclined side which is inclined with respect to each of the first side portion and the second side portion, and
wherein, in each of the first element and the second element, the pad is provided in a pad formation region including a portion resulting from the notch of the second main electrode.

8. The semiconductor device according to claim 7,
wherein each of the plurality of semiconductor elements has a plurality of the pads, and
wherein, in each of the first element and the second element, the plurality of pads are arranged along the inclined side of the notch.

9. The semiconductor device according to claim 7,
wherein, in each of the first element and the second element, a plurality of the pads are arranged along each of the first side portion and the second side portion.

10. The semiconductor device according to claim 9,
wherein the semiconductor element has a temperature sensing diode that detects a temperature of the semiconductor element, and
wherein, in the plan view, the temperature sensing diode is provided in the pad formation region and in the vicinity of the inclined side of the notch.

11. The semiconductor device according to claim 1,
wherein each of the plurality of semiconductor elements has a plurality of the pads,
wherein, in each of the first element and the second element, the plurality of pads include a first pad connected to the signal terminal via the bonding wire,
wherein, in one of the first element and the second element, the plurality of pads include a second pad connected to the signal terminal via the bonding wire, and
wherein the first pad has a length equal to that of the second pad in one of the first direction and the second direction, while having a length larger than that of the second pad in another of the first direction and the second direction.

12. The semiconductor device according to claim 1,
wherein each of the plurality of semiconductor elements has a plurality of the pads,
wherein the plurality of pads include a Kelvin pad that detects a potential of the second main electrode, an anode pad that detects a potential of an anode of a temperature sensing diode provided in the semiconductor element, and a cathode pad that detects a potential of a cathode of the temperature sensing diode,
wherein the Kelvin pad is located adjacent to the anode pad or the cathode pad, and
wherein, in at least one of the first element and the second element, the anode pad or the cathode pad located adjacent to the Kelvin pad is electrically connected to the Kelvin pad.
